(19) United States
(12) Patent Application Publication
(10) Pub. No.: US 2026/0136528 A1
(43) Pub. Date: May 14, 2026

(54) SEMICONDUCTOR DEVICE WITH HORIZONTAL CHANNEL LAYER AND METHOD FOR FABRICATING THE SAME

(71) Applicant: NANYA TECHNOLOGY CORPORATION, NEW TAIPEI CITY (TW)

(72) Inventor: JHEN-YU TSAI, NEW TAIPEI CITY (TW)

(21) Appl. No.: 18/979,665

(22) Filed: Dec. 13, 2024

Related U.S. Application Data
(63) Continuation of application No. 18/941,106, filed on Nov. 8, 2024.

(51) Int. Cl. H10B 12/00

(52) U.S. Cl. CPC H10B 12/30; H10B 12/03; H10B 12/05

(57) ABSTRACT

The present application discloses a semiconductor device and a method for fabricating the semiconductor device. The semiconductor device includes a supporting substrate; and a channel layer positioned parallel to a top surface of the supporting substrate, extending along a first direction, and including, in a sequence along the first direction, a drain, a channel, and a source. A top surface of the channel deviates less than three times its root mean square roughness.

### CROSS-REFERENCE TO RELATED APPLICATION

This application is a continuation application of U.S. Non-Provisional Application No. Ser. No. 18/941,106 filed Nov. 8, 2024, which is incorporated herein by reference in its entirety.

### TECHNICAL FIELD

The present disclosure relates to a semiconductor device and a method for fabricating the semiconductor device, and more particularly, to a semiconductor device with a horizontal channel layer and a method for fabricating the semiconductor device with the horizontal channel layer.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a supporting substrate; and a channel layer positioned parallel to a top surface of the supporting substrate, extending along a first direction, and including, in a sequence along the first direction, a drain, a channel, and a source. A top surface of the channel deviates less than three times its root mean square roughness.

Another aspect of the present disclosure provides a method for fabricating a semiconductor device including providing a supporting substrate; forming a channel layer parallel to a top surface of the supporting substrate, extending along a first direction, and including, in a sequence along the first direction, a drain, a channel, and a source; conformally forming an interface insulating layer covering the channel layer; and performing a first thermal treatment to the channel layer and the interface insulating layer. A top surface of the channel layer deviates less than three times its root mean square roughness.

Another aspect of the present disclosure provides a method for fabricating a semiconductor device including providing a supporting substrate; forming a channel layer parallel to a top surface of the supporting substrate, extending along a first direction, and including, in a sequence along the first direction, a drain, a channel, and a source; conformally forming a word line dielectric layer covering the channel of the channel layer; and performing a second thermal treatment to the channel layer and the word line dielectric layer. A top surface of the channel deviates less than three times its root mean square roughness.

Due to the design of the semiconductor device of the present disclosure, the surface roughness (or interface roughness) of the channel layer may be improved and the stress of channel layer may be reduced by employing the thermal treatment(s). As a result, the performance of the semiconductor device may be improved. Additionally, the gate induced drain leakage may be reduced by employing the thicker word line dielectric layer consisting of the inner word line dielectric layer and the outer word line dielectric layer. As a result, the performance (such as retention time) of the semiconductor device may be improved. Furthermore, the outer word line dielectric layer including the high-k dielectric material may improve drain current for the semiconductor device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIG. 2 illustrates, in a schematic top-view diagram, an intermediate semiconductor device;

FIG. 3 is a schematic cross-sectional view diagram taken along lines A-A′, B-B′, C-C′, D-D′, and E-E′ in FIG. 2;

FIG. 4 illustrates, in a schematic top-view diagram, an intermediate semiconductor device;

FIG. 5 is a schematic cross-sectional view diagram taken along lines A-A′, B-B′, C-C′, D-D′, and E-E′ in FIG. 4

FIG. 6 illustrates, in a schematic top-view diagram, an intermediate semiconductor device;

FIG. 7 is a schematic cross-sectional view diagram taken along lines A-A′, B-B′, C-C′, D-D′, and E-E′ in FIG. 6;

FIG. 8 illustrates, in a schematic top-view diagram, an intermediate semiconductor device;

FIG. 9 is a schematic cross-sectional view diagram taken along lines A-A′, B-B′, C-C′, D-D′, and E-E′ in FIG. 8

FIG. 10 illustrates, in a schematic top-view diagram, an intermediate semiconductor device;

FIG. 11 is a schematic cross-sectional view diagram taken along lines A-A′, B-B′, C-C′, D-D′, and E-E′ in FIG. 10;

FIG. 12 illustrates, in a schematic top-view diagram, an intermediate semiconductor device;

FIG. 13 is a schematic cross-sectional view diagram taken along lines A-A′, B-B′, C-C′, D-D′, and E-E′ in FIG. 12;

FIG. 14 illustrates, in a schematic top-view diagram, an intermediate semiconductor device;

FIGS. 15 and 16 are schematic cross-sectional view diagrams taken along lines A-A′, B-B′, C-C′, D-D′, and E-E′ in FIG. 14 illustrating part of the flow for fabricating the semiconductor device;

FIG. 17 illustrates, in a schematic top-view diagram, an intermediate semiconductor device;

FIGS. 18 and 19 are schematic cross-sectional view diagrams taken along lines A-A′, B-B′, C-C′, D-D′, and E-E′ in FIG. 17 illustrating part of the flow for fabricating the semiconductor device;

FIG. 20 illustrates, in a schematic top-view diagram, an intermediate semiconductor device;

FIGS. 21 to 26 are schematic cross-sectional view diagrams taken along lines A-A′, B-B′, C-C′, D-D′, and E-E′ in FIG. 20 illustrating part of the flow for fabricating the semiconductor device;

FIG. 27 illustrates, in a schematic top-view diagram, an intermediate semiconductor device;

FIG. 28 is a schematic cross-sectional view diagram taken along lines A-A′, B-B′, C-C′, D-D′, and E-E′ in FIG. 27;

FIG. 29 illustrates, in a schematic top-view diagram, an intermediate semiconductor device;

FIG. 30 is a schematic cross-sectional view diagram taken along lines A-A′, B-B′, C-C′, D-D′, and E-E′ in FIG. 29;

FIG. 31 illustrates, in a schematic top-view diagram, an intermediate semiconductor device;

FIGS. 32 and 33 are schematic cross-sectional view diagrams taken along lines A-A′, B-B′, C-C′, D-D′, and E-E′ in FIG. 31 illustrating part of the flow for fabricating the semiconductor device;

FIG. 34 illustrates, in a schematic top-view diagram, an intermediate semiconductor device;

FIG. 35 is a schematic cross-sectional view diagram taken along lines A-A′, B-B′, C-C′, D-D′, and E-E′ in FIG. 34;

FIG. 36 illustrates, in a schematic top-view diagram, an intermediate semiconductor device;

FIGS. 37 and 38 are schematic cross-sectional view diagrams taken along lines A-A′, B-B′, C-C′, D-D′, and E-E′ in FIG. 36 illustrating part of the flow for fabricating the semiconductor device;

FIG. 39 illustrates, in a schematic top-view diagram, an intermediate semiconductor device;

FIGS. 40 and 41 are schematic cross-sectional view diagrams taken along lines A-A′, B-B′, C-C′, D-D′, E-E′, and F-F′ in FIG. 39 illustrating part of the flow for fabricating the semiconductor device;

FIG. 42 illustrates, in a schematic top-view diagram, an intermediate semiconductor device;

FIG. 43 is a schematic cross-sectional view diagram taken along lines A-A′, B-B′, C-C′, D-D′, E-E′, and F-F′ in FIG. 42;

FIG. 44 illustrates, in a schematic top-view diagram, an intermediate semiconductor device;

FIGS. 45 and 46 are schematic cross-sectional view diagrams taken along lines A-A′, B-B′, C-C′, D-D′, E-E′, and F-F′ in FIG. 44 illustrating part of the flow for fabricating the semiconductor device;

FIG. 47 illustrates, in a schematic top-view diagram, an intermediate semiconductor device in accordance with another embodiment;

FIG. 48 is a schematic cross-sectional view diagram taken along lines A-A′, B-B′, C-C′, D-D′, E-E′, and F-F′ in FIG. 47;

FIG. 49 illustrates, in a schematic top-view diagram, an intermediate semiconductor device in accordance with another embodiment; and

FIGS. 50 to 54 are schematic cross-sectional view diagrams taken along lines A-A′, B-B′, C-C′, D-D′, E-E′, and F-F′ in FIG. 49 illustrating part of a flow for fabricating a semiconductor device in accordance with another embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

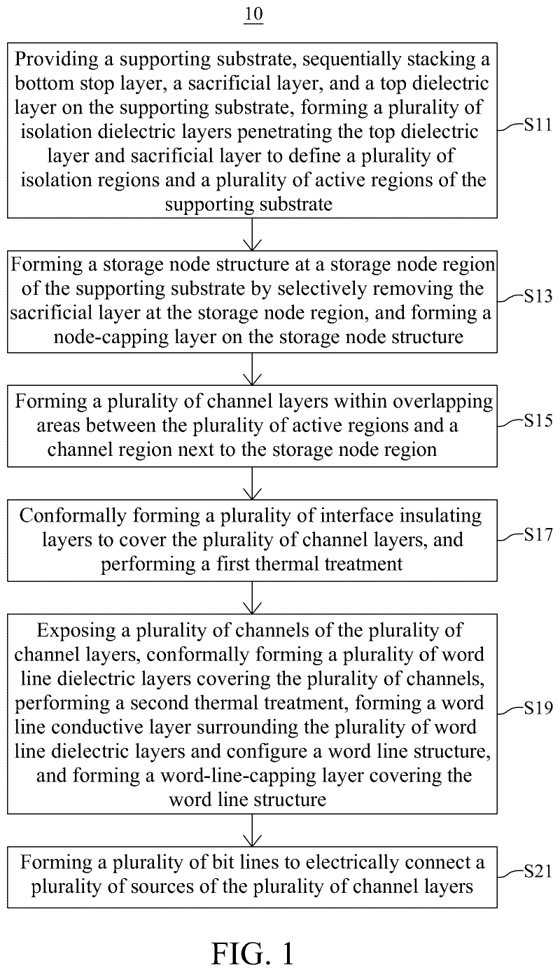

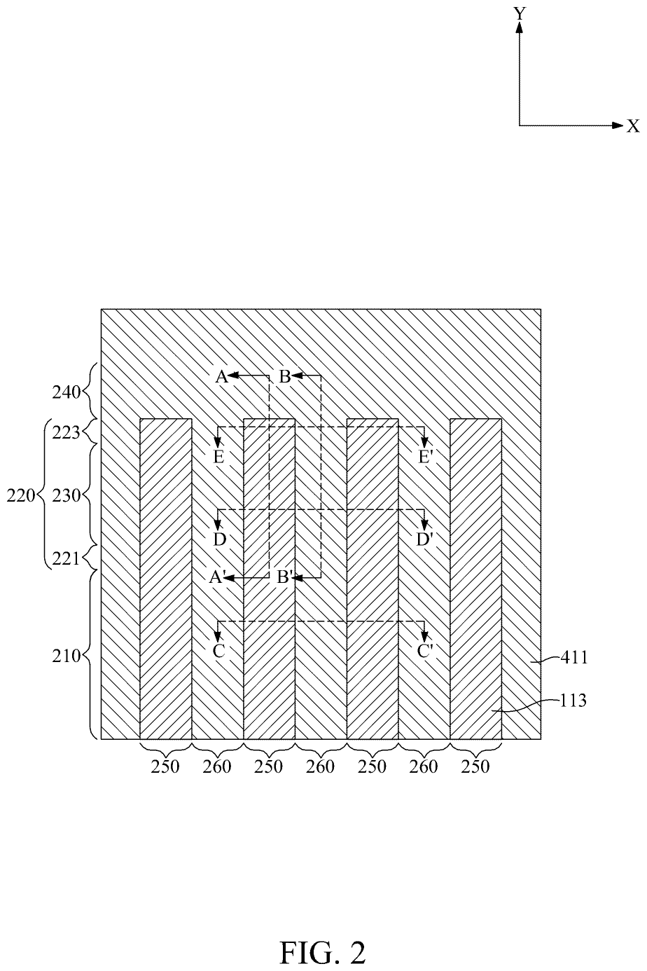

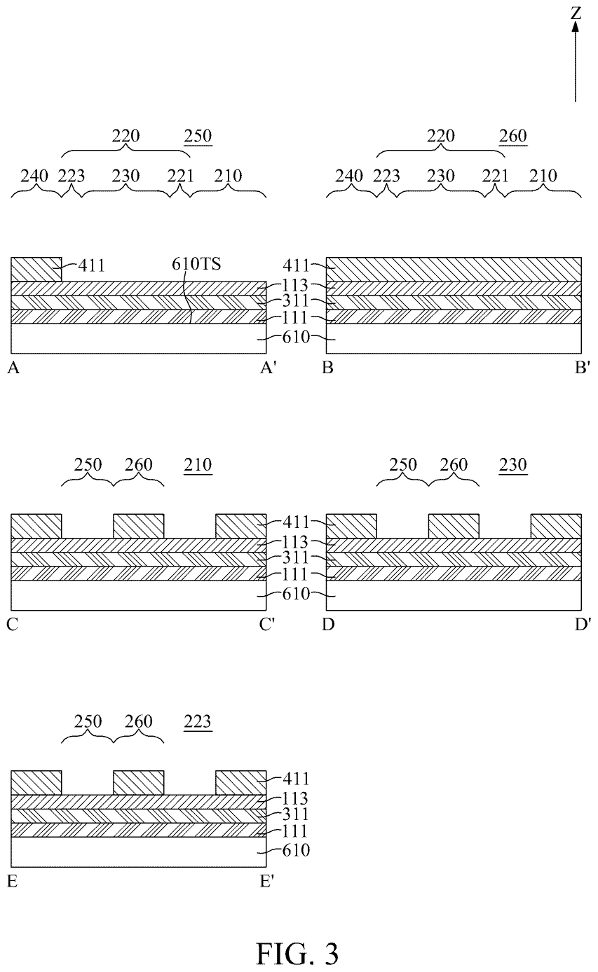

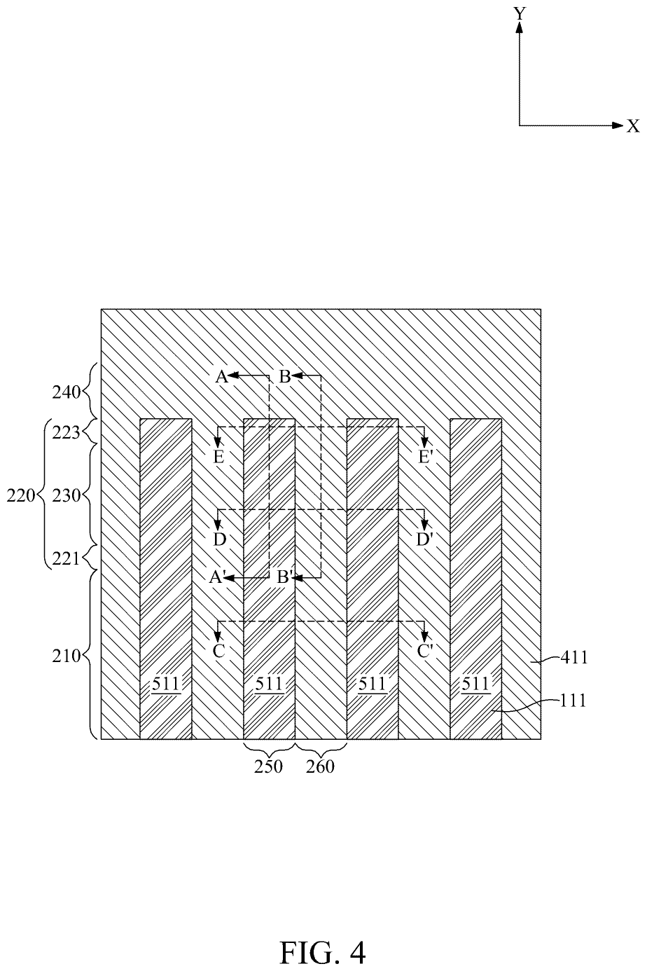

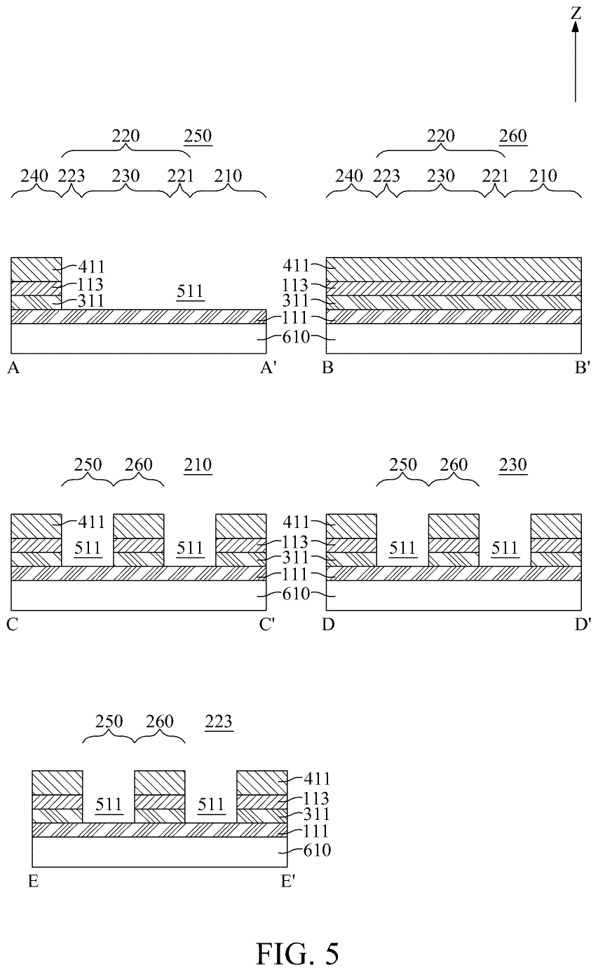

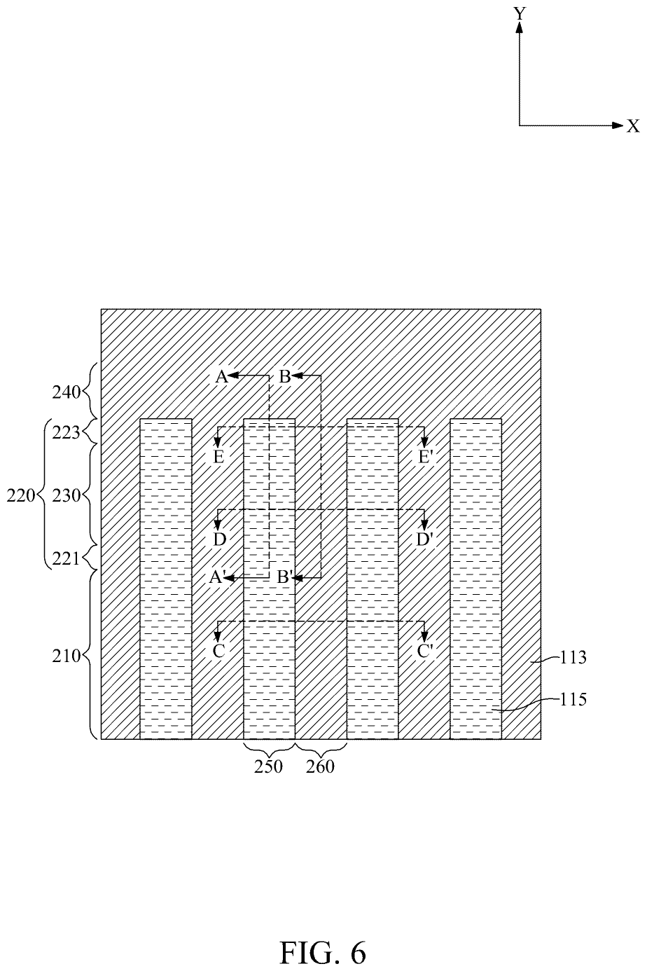

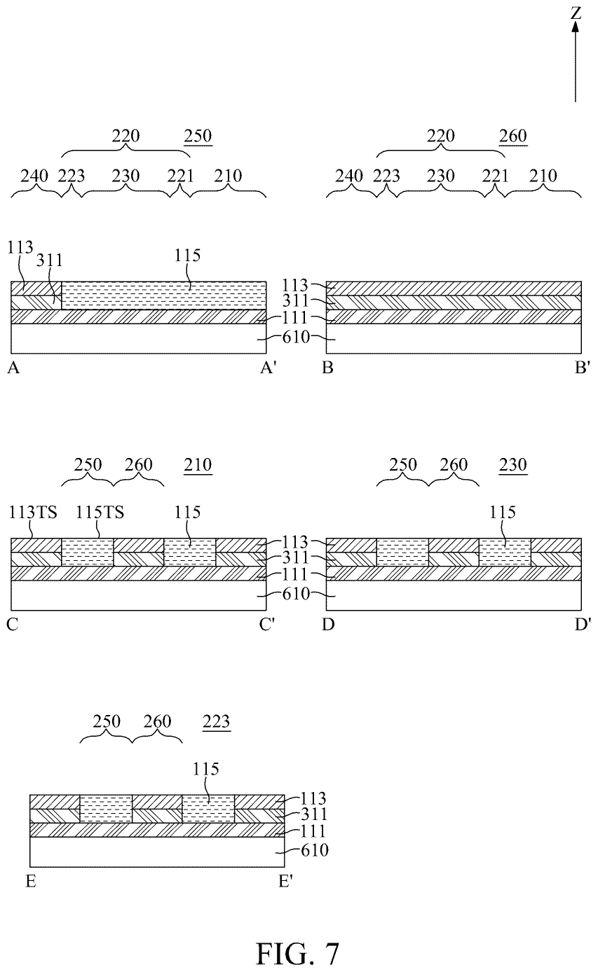

FIG. 1 illustrates, in a flowchart diagram form, a method 10 for fabricating a semiconductor device 1A in accordance with one embodiment of the present disclosure. FIG. 2 illustrates, in a schematic top-view diagram, an intermediate semiconductor device in accordance with one embodiment of the present disclosure. FIG. 3 is a schematic cross-sectional view diagram taken along lines A-A′, B-B′, C-C′, D-D′, and E-E′ in FIG. 2. FIG. 4 illustrates, in a schematic top-view diagram, an intermediate semiconductor device in accordance with one embodiment of the present disclosure. FIG. 5 is a schematic cross-sectional view diagram taken along lines A-A′, B-B′, C-C′, D-D′, and E-E′ in FIG. 4. FIG. 6 illustrates, in a schematic top-view diagram, an intermediate semiconductor device in accordance with one embodiment of the present disclosure. FIG. 7 is a schematic cross-sectional view diagram taken along lines A-A′, B-B′, C-C′, D-D′, and E-E′ in FIG. 6.

With reference to FIGS. 1 to 7, at step S11, a supporting substrate 610 may be provided, a bottom stop layer 111, a sacrificial layer 311, and a top dielectric layer 113 may be sequentially stacked on the supporting substrate 610, a plurality of isolation dielectric layers 115 may be formed penetrating the top dielectric layer 113 and sacrificial layer 311 to define a plurality of isolation regions 250 and a plurality of active regions 260 of the supporting substrate 610.

With reference to FIGS. 2 and 3, the supporting substrate 610 may include a silicon substrate, a germanium substrate, or a silicon-germanium substrate. In some embodiments, the supporting substrate 610 may include a non-semiconductive substrate. In some embodiments, the supporting substrate 610 may include a glass substrate, a plastic substrate, a ceramic substrate, or a conductive substrate. The glass substrate may include soda-lime glass, alkali-free glass, or fused silica. The plastic substrate may include polyethylene terephthalate, polyimide, or polycarbonate. The conductive substrate may include metal foil. In some embodiments, the supporting substrate 610 may include an insulating substrate.

In a top-view perspective, the supporting substrate 610 and the space above it may be divided into different regions. Each region may include a portion of the supporting substrate 610 and the corresponding space above its top surface 610TS. Each region may include a rectangular area, with its long axis aligned along either the X direction or the Y direction (referred to as a region along the X direction or Y direction). It should be noted that these regions are defined for illustrative purposes and may not be completely distinct from each other. For example, a region along the X direction and a region along the Y direction may partially overlap. Additionally, an element (or feature) within (in, or at) a region may be described as the region of the element.

In some embodiments, the supporting substrate 610 may include, in sequence along the Y direction, a storage node region 210, a channel region 220, a word line region 230, and a bit line region 240, all along the X direction. The channel region 220 may include, in sequence along the Y direction, a first source/drain region 221, a word line region 230, and a second source/drain region 223.

Additionally, the supporting substrate 610 may include the plurality of isolation regions 250 and active regions 260, both along the Y direction and alternately arranged along the X direction. Different portions of each isolation region 250 may partially overlap with the storage node region 210, the channel region 220, the word line region 230, and the bit line region 240, respectively. Different portions of each active region 260 may partially overlap with the storage node region 210, the channel region 220, the word line region 230, and the bit line region 240, respectively.

For brevity, clarity, and convenience of description, only one isolation region 250 and one active region 260 are described.

With reference to FIGS. 2 and 3, the bottom stop layer 111 may be formed on the supporting substrate 610. In some embodiments, the bottom stop layer 111 may be formed of, for example, silicon nitride, silicon carbonitride, silicon oxynitride, silicon oxycarbide, silicon oxide, boron nitride, silicon boron nitride, phosphorus boron nitride, boron carbon silicon nitride, or other applicable insulating material. In some embodiments, the bottom stop layer 111 may be formed by, for example, chemical vapor deposition, plasma-enhanced chemical vapor deposition, atomic layer deposition, or other applicable deposition processes.

In some embodiments, the supporting substrate 610 may be served as an etching stop layer. In some embodiments, the bottom stop layer 111 may be optional when the supporting substrate 610 is formed of a material having etching selectivity for subsequent etching processes.

With reference to FIGS. 2 and 3, the sacrificial layer 311 may be formed on the bottom stop layer 111. The top dielectric layer 113 may be formed on the sacrificial layer 311. In some embodiments, the sacrificial layer 311 may be formed of a material having etching selectivity to the top dielectric layer 113. In some embodiments, the sacrificial layer 311 may be formed of a material having etching selectivity to the top dielectric layer 113 and the bottom stop layer 111. In some embodiments, the sacrificial layer 311 may be formed of, for example, polycrystalline silicon, polycrystalline germanium, polycrystalline silicon germanium, or an oxide-based semiconductor composition. In some embodiments, the sacrificial layer 311 may be formed by, for example, chemical vapor deposition, plasma-enhanced chemical vapor deposition, atomic layer deposition, or other applicable deposition processes.

In some embodiments, the top dielectric layer 113 may be formed of a material having etching selectivity to the sacrificial layer 311. In some embodiments, the top dielectric layer 113 may be formed of a material having etching selectivity to the sacrificial layer 311 and the bottom stop layer 111. In some embodiments, the top dielectric layer 113 and the bottom stop layer 111 may be formed of the same material. In some embodiments, the top dielectric layer 113 and the bottom stop layer 111 may be formed of different materials. In some embodiments, the top dielectric layer 113 may be formed of, for example, silicon nitride, silicon oxide, silicon carbonitride, silicon oxycarbide, or other applicable insulating material. In some embodiments, the top dielectric layer 113 may be formed by, for example, chemical vapor deposition, plasma-enhanced chemical vapor deposition, atomic layer deposition, or other applicable deposition processes.

With reference to FIGS. 2 and 3, an isolation mask 411 may be formed on the top dielectric layer 113. In some embodiments, the isolation mask 411 may be a photoresist layer. The isolation mask 411 may include a pattern which partially exposes the isolation region 250. Detailedly, the overlapped area (or portion) between the isolation region 250 and the storage node region 210 and the overlapped area between the isolation region 250 and the channel region 220 may be exposed through the isolation mask 411.

With reference to FIGS. 4 and 5, a plurality of vertical openings 511 may be formed by performing an etching process (also referred to as isolation etching process) to remove the exposed top dielectric layer 113 and the underlying sacrificial layer 311. Detailedly, the top dielectric layer 113 and the sacrificial layer 311 located at the overlapping areas between the isolation region 250 and the storage node region 210, as well as between the isolation region 250 and the channel region 220, may be removed through the etching process, resulting in the formation of the plurality of vertical openings 511. The plurality of vertical openings 511 may separate the top dielectric layer 113 and the underlying sacrificial layer 311 located at the plurality of active regions 260. In some embodiments, the bottom stop layer 111 located at (or within) the overlapping areas aforementioned may be removed or partially removed. The isolation mask 411 may be removed after the formation of the vertical opening 511.

In some embodiments, the isolation etching process may be an anisotropic etching process. In some embodiments, the isolation etching process may include multiple stages, with each stage providing tailored etching chemistry to selectively remove the target layer.

For brevity, clarity, and convenience of description, only one isolation dielectric layer 115 is described.

With reference to FIGS. 6 and 7, the isolation dielectric layer 115 may be formed in the vertical opening 511. A planarization process, such as chemical mechanical polishing, may be performed until the top surface 113TS of top dielectric layer 113 is exposed to remove excess material and provide a substantially flat surface for subsequent processing steps. In a top-view perspective, the isolation dielectric layer 115 may be located at the overlapped area between the isolation region 250 and the storage node region 210 and the overlapped area between the isolation region 250 and the channel region 220. The isolation dielectric layer 115 may separate the top dielectric layer 113 and the underlying sacrificial layer 311 located at the plurality of active regions 260. In a cross-sectional perspective, the isolation dielectric layer 115 may penetrate the top dielectric layer 113 and the sacrificial layer 311. In some embodiments, the top surface 113TS of the top dielectric layer 113 and the top surface 115TS of the isolation dielectric layer 115 may be substantially coplanar.

In some embodiments, the isolation dielectric layer 115 may be formed of a material having etching selectivity to the top dielectric layer 113. In some embodiments, the isolation dielectric layer 115 may be formed of a material having etching selectivity to the sacrificial layer 311. In some embodiments, the isolation dielectric layer 115 may be formed of a material having etching selectivity to the bottom stop layer 111. In some embodiments, the isolation dielectric layer 115 may be formed of, for example, silicon nitride, silicon oxide, silicon carbonitride, silicon oxycarbide, or other applicable insulating material. In some embodiments, the isolation dielectric layer 115 may be formed by, for example, chemical vapor deposition, plasma-enhanced chemical vapor deposition, or other applicable deposition processes.

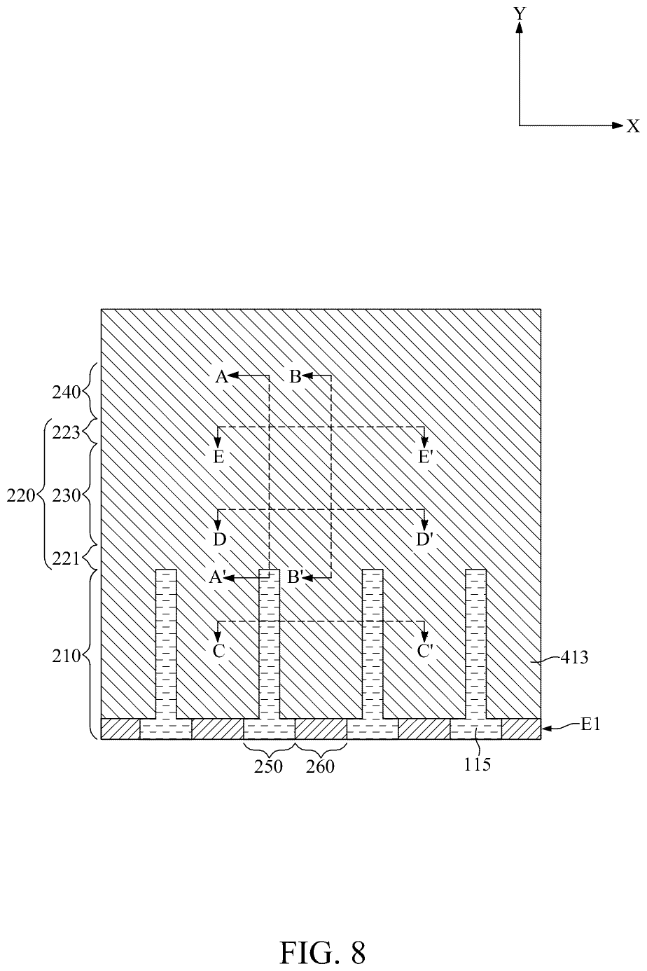

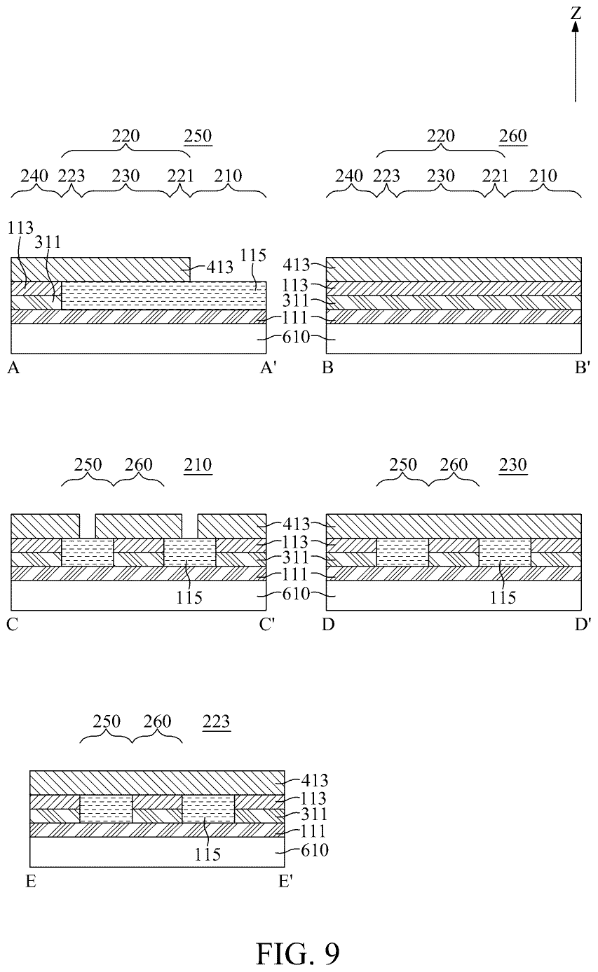

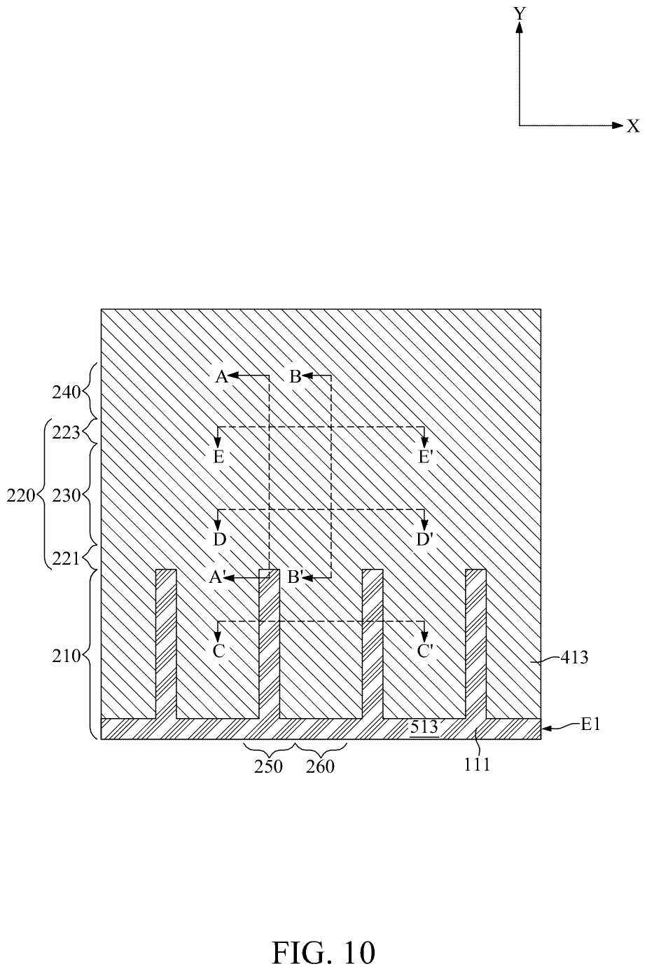

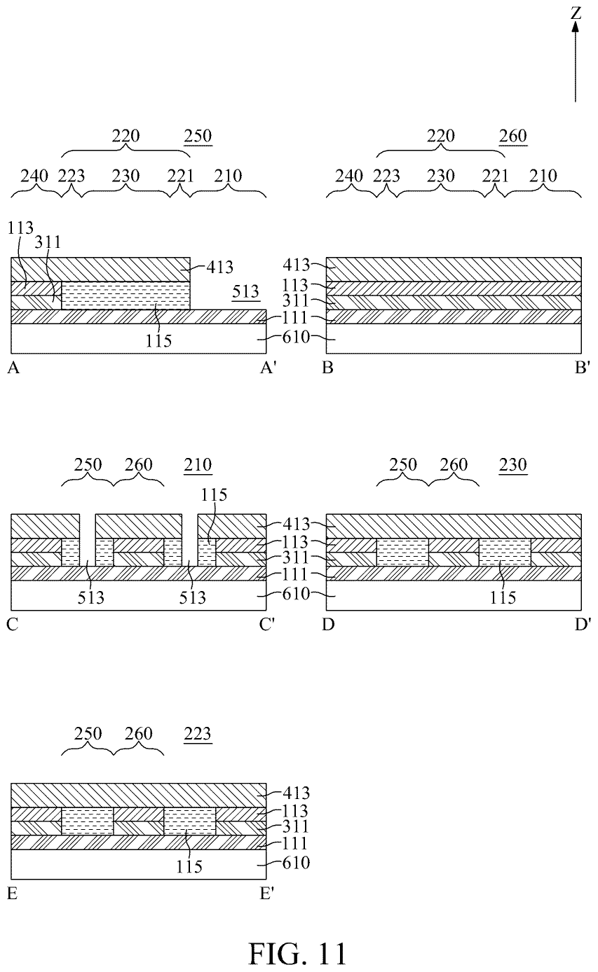

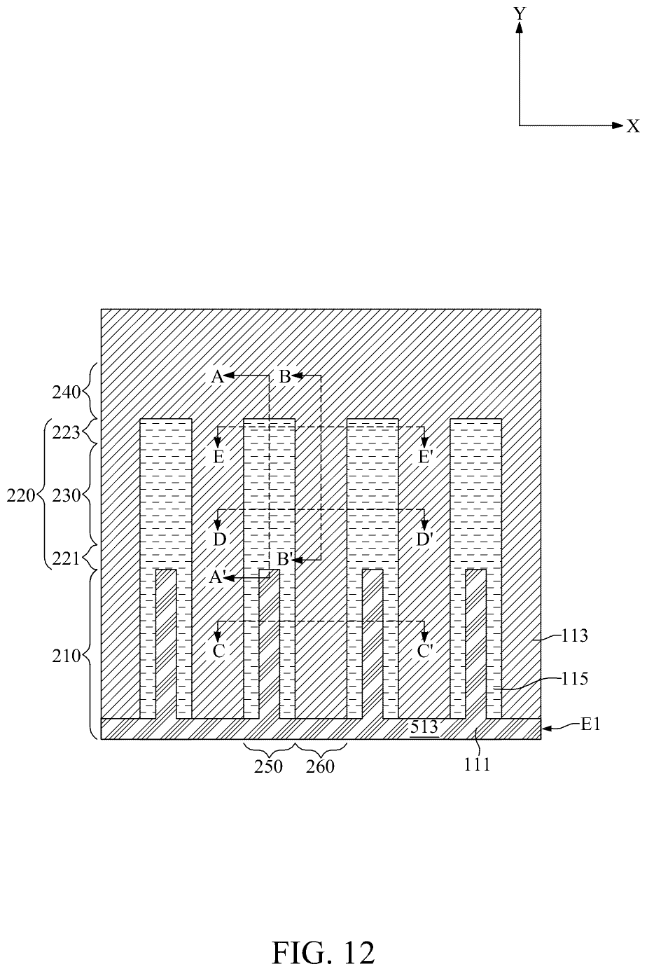

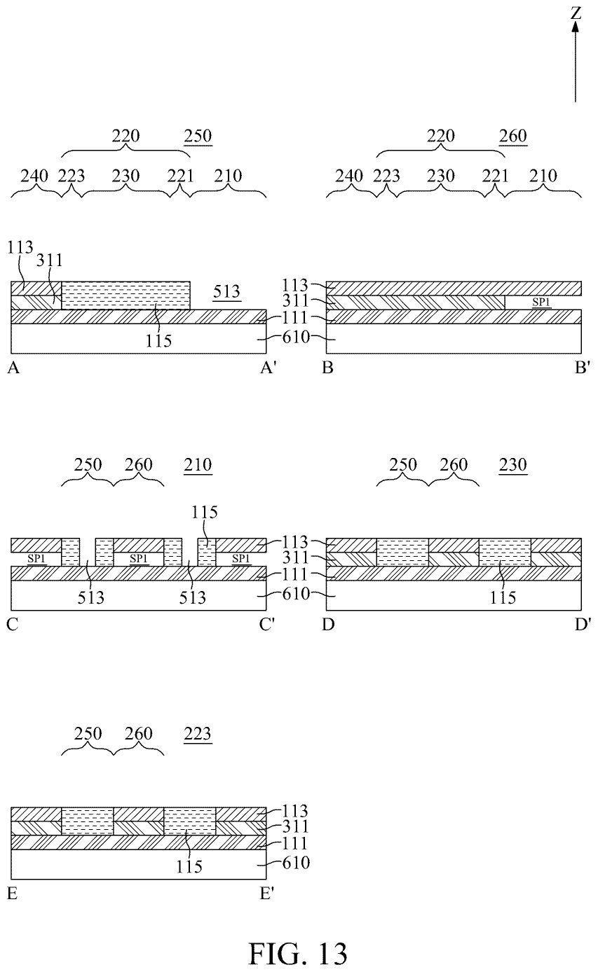

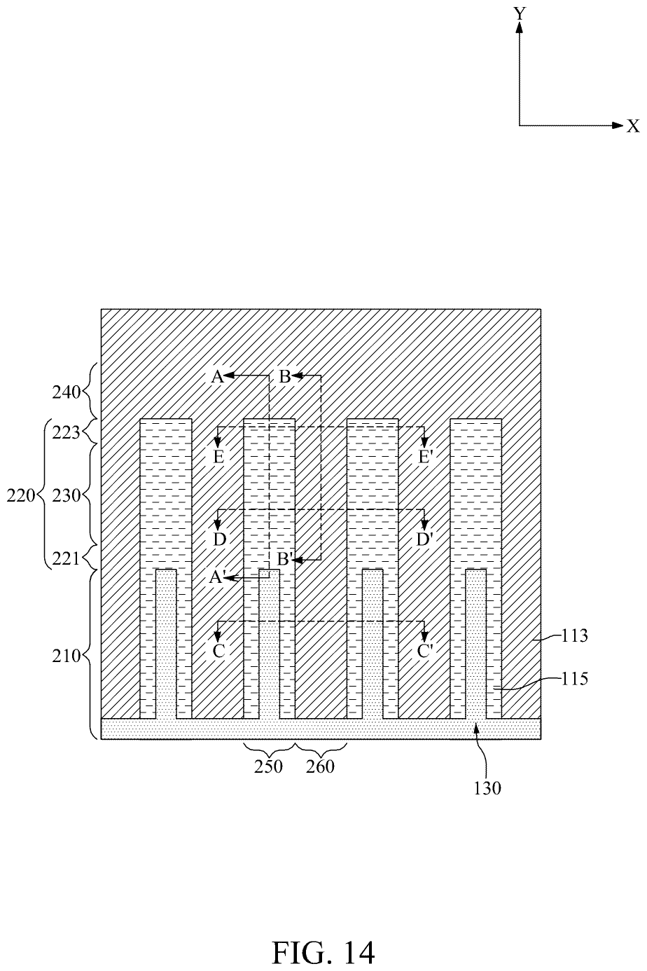

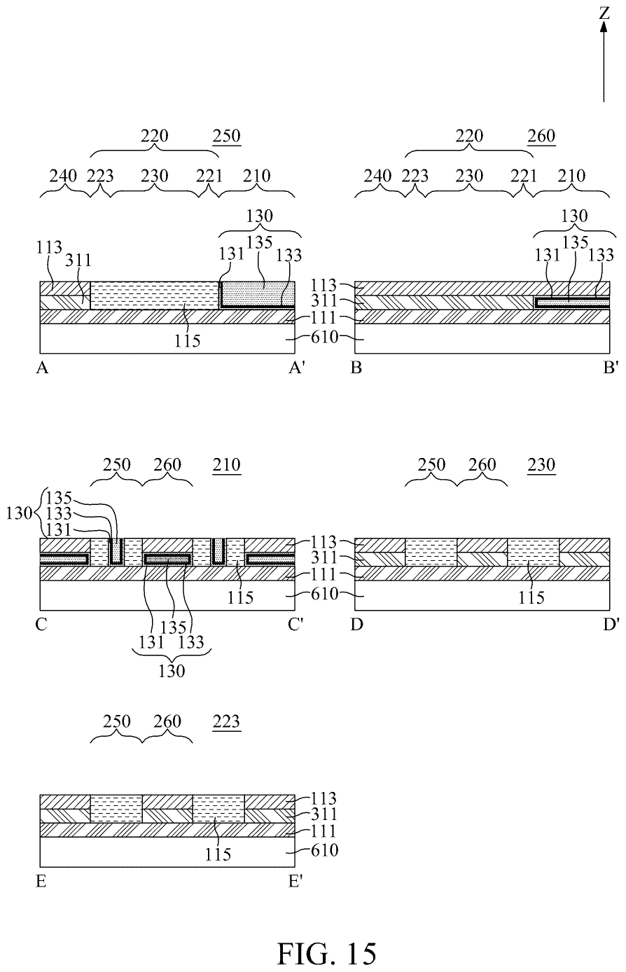

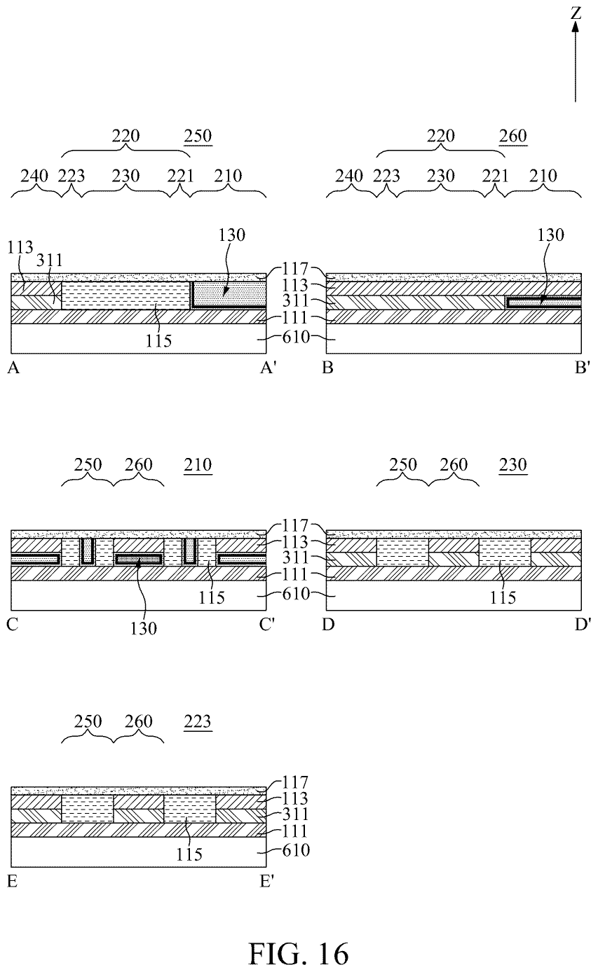

FIG. 8 illustrates, in a schematic top-view diagram, an intermediate semiconductor device in accordance with one embodiment of the present disclosure. FIG. 9 is a schematic cross-sectional view diagram taken along lines A-A′, B-B′, C-C′, D-D′, and E-E′ in FIG. 8. FIG. 10 illustrates, in a schematic top-view diagram, an intermediate semiconductor device in accordance with one embodiment of the present disclosure. FIG. 11 is a schematic cross-sectional view diagram taken along lines A-A′, B-B′, C-C′, D-D′, and E-E′ in FIG. 10. FIG. 12 illustrates, in a schematic top-view diagram, an intermediate semiconductor device in accordance with one embodiment of the present disclosure. FIG. 13 is a schematic cross-sectional view diagram taken along lines A-A′, B-B′, C-C′, D-D′, and E-E′ in FIG. 12. FIG. 14 illustrates, in a schematic top-view diagram, an intermediate semiconductor device in accordance with one embodiment of the present disclosure. FIGS. 15 and 16 are schematic cross-sectional view diagrams taken along lines A-A′, B-B′, C-C′, D-D′, and E-E′ in FIG. 14 illustrating part of the flow for fabricating the semiconductor device 1A in accordance with one embodiment of the present disclosure.

With reference to FIG. 1 and FIGS. 8 to 16, at step S13, a storage node structure 130 may be formed at the storage node region 210 of the supporting substrate 610 by selectively removing the sacrificial layer 311 at the storage node region 210, and a node-capping layer 117 may be formed on the storage node structure 130.

With reference to FIGS. 8 and 9, a node-exposing mask 413 may be formed on the top dielectric layer 113 and the isolation dielectric layer 115. In some embodiments, the node-exposing mask 413 may be a photoresist layer. The node-exposing mask 413 may include a pattern which partially exposes the storage node region 210. Detailedly, the top dielectric layer 113 away from the channel region 220 may be exposed (location indicated by the arrow E1), while the isolation dielectric layer 115 farthest from the channel region 220 may be fully exposed (location indicated by arrow E1). The isolation dielectric layer 115 within the storage node region 210 may be partially exposed and the isolation dielectric layer 115 within the channel region 220 may be masked by the node-exposing mask 413.

With reference to FIGS. 10 and 11, a vertical opening 513 may be formed by performing an etching process (also referred to as a node-exposing etching process) to remove the exposed top dielectric layer 113, the underlying sacrificial layer 311, and the exposed isolation dielectric layer 115. Detailedly, the top dielectric layer 113 and the underlying sacrificial layer 311, located away from the channel region 220 (as indicated by the arrow E1), may be removed, exposing the sacrificial layer 311 within the overlapping area between the active region 260 and the storage node region 210. The isolation dielectric layer 115 farthest from the channel region 220 may also be removed (as indicated by the arrow E1). The remaining isolation dielectric layer 115 within the storage node region 210 may be partially removed. The vertical opening 513 may divide the isolation dielectric layer 115 within the storage node region 210 into two segments extending along the Y direction, respectively. However, the isolation dielectric layer 115 within the storage node region 210 may continue to separate adjacent active regions 260.

In some embodiments, the node-exposing etching process may be an anisotropic etching process. In some embodiments, the node-exposing etching process may include multiple stages, with each stage providing tailored etching chemistry to selectively remove the target layer. The node-exposing mask 413 may be removed after the formation of the vertical opening 513.

With reference to FIGS. 12 and 13, the sacrificial layer 311 within the storage node region 210 may be selectively removed, resulting in a space SP1. The sacrificial layer 311 within the channel region 220 may be exposed through the space SP1. In some embodiments, the removal of the sacrificial layer 311 may be achieved by an isotropic etching process.

The storage node structure 130 may be subsequently formed in the space SP1 and the vertical opening 513. In some embodiments, the storage node structure 130 may be or include memory elements capable of storing data. In some embodiments, the storage node structure 130 may be a memory element using one of a capacitor, a magnetic tunnel junction pattern, and/or a variable resistance body which includes a phase change material, etc. In the present disclosure, the storage node structure 130 may be a capacitor.

With reference to FIGS. 14 and 15, a first electrode 131 may be conformally formed in the space SP1 and the vertical opening 513. In some embodiments, the first electrode 131 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the first electrode 131 may be formed by, for example, atomic layer deposition or other applicable deposition processes.

With reference to FIGS. 14 and 15, a node dielectric layer 133 may be conformally formed on the first electrode 131. In some embodiments, the node dielectric layer 133 may be formed of, for example, silicon oxide, silicon nitride, a high-k dielectric material, or other applicable dielectric materials. In some embodiments, the node dielectric layer 133 may be formed by, for example, atomic layer deposition or other applicable deposition processes.

With reference to FIGS. 14 and 15, a second electrode 135 may be formed to fill the space SP1 and the vertical opening 513. A planarization process, such as chemical mechanical polishing, may be performed until the top dielectric layer 113 is exposed to remove excess material and provide a substantially flat surface for subsequent processing steps. In some embodiments, the second electrode 135 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the second electrode 135 may be formed by, for example, atomic layer deposition or other applicable deposition processes. The first electrode 131, the node dielectric layer 133, and the second electrode 135 together configure the storage node structure 130. The node dielectric layer 133 may electrically isolate the first electrode 131 and the second electrode 135. The first electrode 131 may contact the sacrificial layer 311 within the overlapping area between the active region 260 and the channel region 220.

With reference to FIG. 16, the node-capping layer 117 may be formed on the top dielectric layer 113, the isolation dielectric layer 115, and the storage node structure 130. In some embodiments, the node-capping layer 117 may be formed of a material having etching selectivity to the bottom stop layer 111. In some embodiments, the node-capping layer 117 may be formed of a material having etching selectivity to the top dielectric layer 113. In some embodiments, the node-capping layer 117 may be formed of a material having etching selectivity to the isolation dielectric layer 115. In some embodiments, the node-capping layer 117 may be formed of a material having etching selectivity to the sacrificial layer 311. In some embodiments, the node-capping layer 117 may be formed of, for example, silicon nitride, silicon oxide, silicon carbonitride, silicon oxycarbide, boron nitride, silicon boron nitride, phosphorus boron nitride, boron carbon silicon nitride, or other applicable insulating material. In some embodiments, the node-capping layer 117 may be formed by, for example, chemical vapor deposition, plasma-enhanced chemical vapor deposition, atomic layer deposition, or other applicable deposition processes.

It should be noted that the node-capping layer 117 is not shown in the top-view diagrams for clarity.

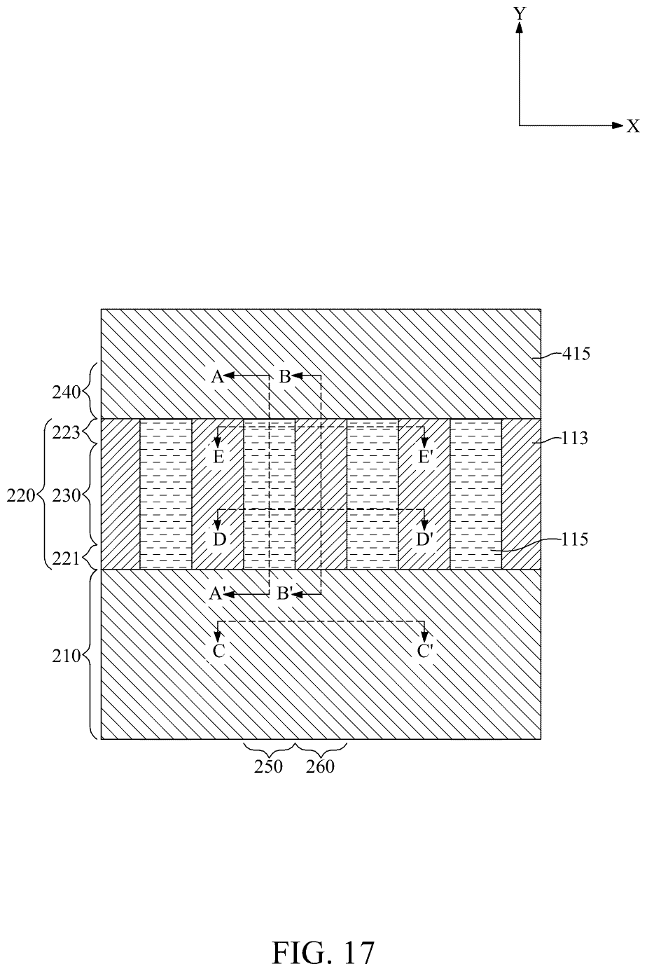

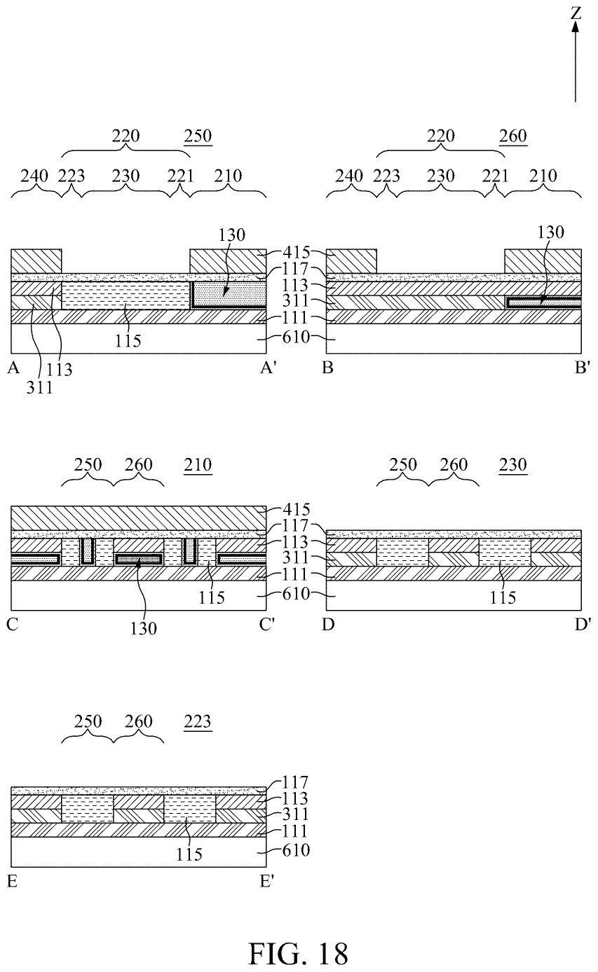

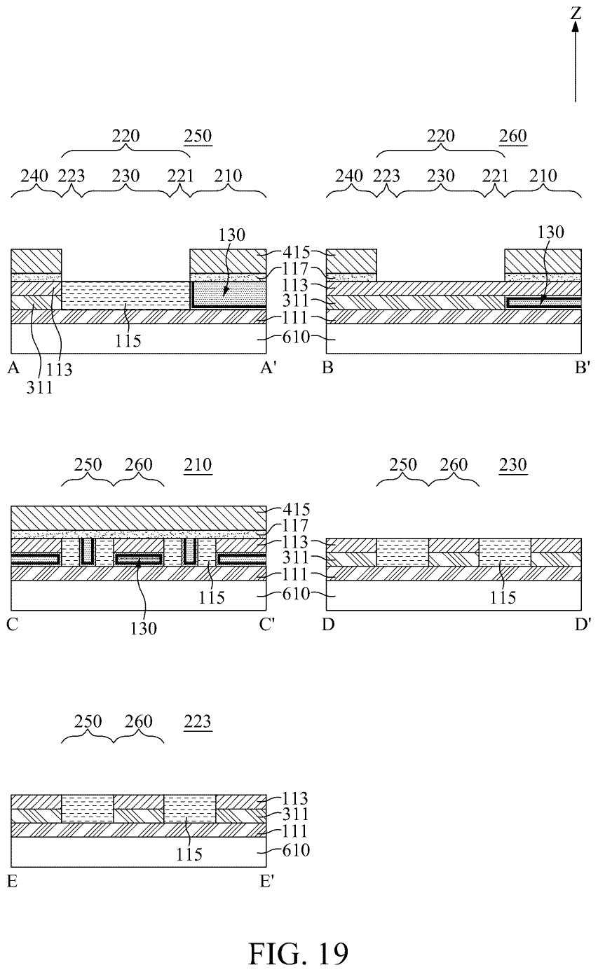

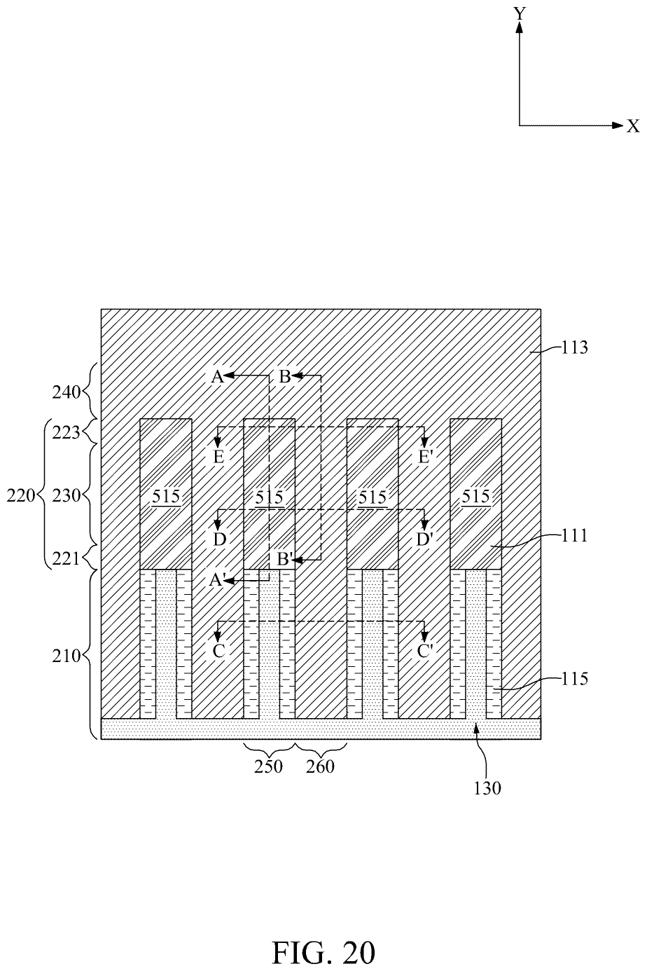

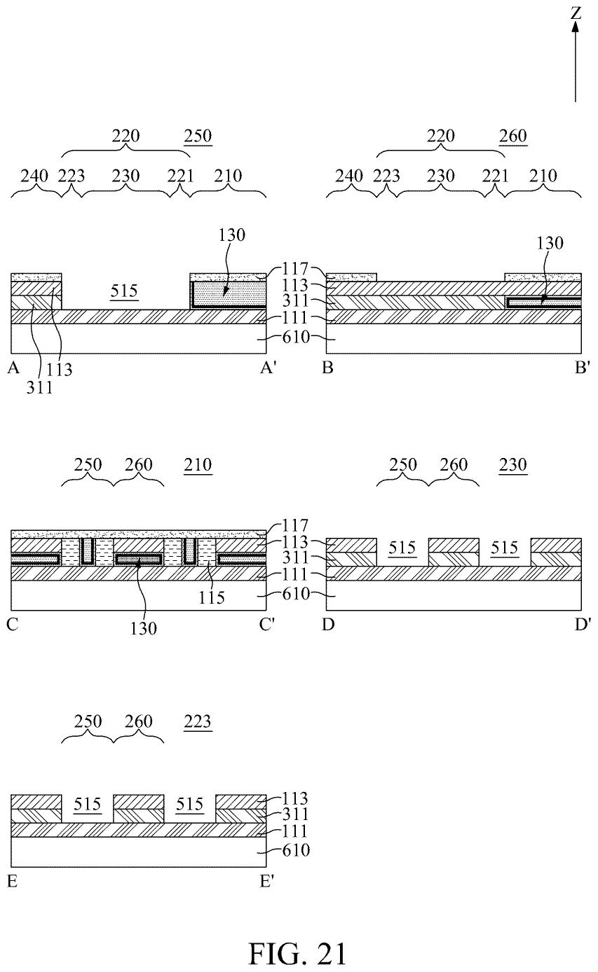

FIG. 17 illustrates, in a schematic top-view diagram, an intermediate semiconductor device in accordance with one embodiment of the present disclosure. FIGS. 18 and 19 are schematic cross-sectional view diagrams taken along lines A-A′, B-B′, C-C′, D-D′, and E-E′ in FIG. 17 illustrating part of the flow for fabricating the semiconductor device 1A in accordance with one embodiment of the present disclosure. FIG. 20 illustrates, in a schematic top-view diagram, an intermediate semiconductor device in accordance with one embodiment of the present disclosure. FIGS. 21 to 26 are schematic cross-sectional view diagrams taken along lines A-A′, B-B′, C-C′, D-D′, and E-E′ in FIG. 20 illustrating part of the flow for fabricating the semiconductor device 1A in accordance with one embodiment of the present disclosure.

With reference to FIG. 1 and FIGS. 17 to 24, at step S15, a plurality of channel layers 150 may be formed within overlapping areas between the plurality of active regions 260 and the channel region 220 next to the storage node region 210.

With reference to FIGS. 17 and 18, a channel-exposing mask 415 may be formed on the node-capping layer 117. In some embodiments, the channel-exposing mask 415 may be a photoresist layer. The channel-exposing mask 415 may include a pattern which completely exposes the channel region 220.

With reference to FIG. 19, the pattern of the channel-exposing mask 415 may be transferred to the node-capping layer 117 by an etching process. In some embodiments, the etching process may be an anisotropic etching process. The isolation dielectric layer 115 and the top dielectric layer 113 within the channel region 220 may be exposed after the etching process. In some embodiments, the channel-exposing mask 415 may be removed after the pattern transfer. In some embodiments, the channel-exposing mask 415 may be removed after the formation of the vertical opening 515 which will be illustrated later.

With reference to FIGS. 20 and 21, a plurality of vertical openings 515 may be formed by selectively removing the isolation dielectric layer 115 within the channel region 220 using an etching process (also referred to as the first channel-exposing etching process). The sacrificial layer 311 within the channel region 220 may be exposed through the plurality of vertical openings 515.

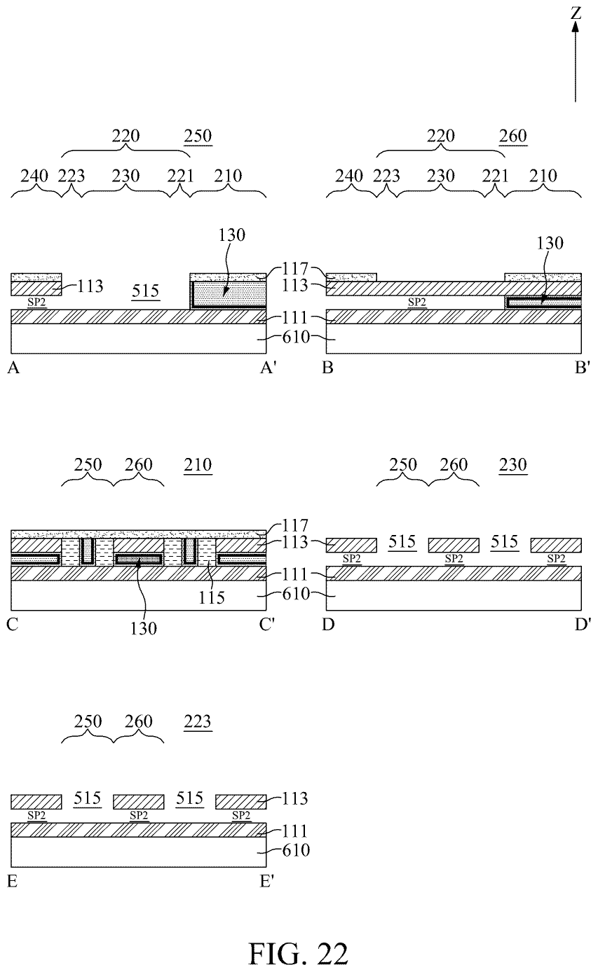

With reference to FIG. 22, a plurality of spaces SP2 may be formed by selectively removing the sacrificial layer 311 within the channel region 220. Detailedly, the plurality of spaces SP2 may be at the overlapping areas between the plurality of active regions 260 and the channel region 220. The plurality of spaces SP2 may be communicated with the plurality of vertical openings 515. In some embodiments, the removal of the sacrificial layer 311 may be achieved by an etching process such as a selective isotropic etching process.

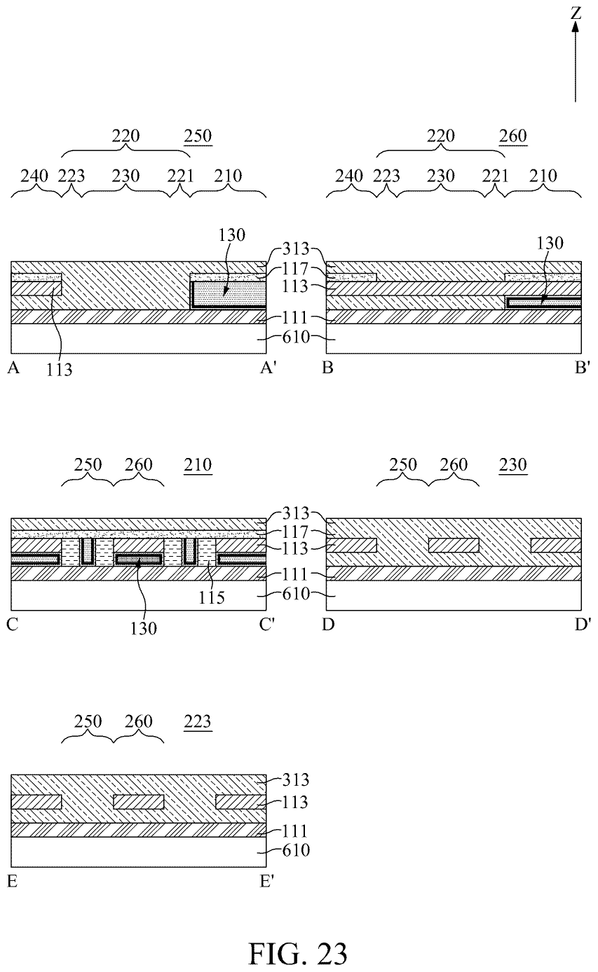

With reference to FIG. 23, the layer of channel material 313 may be formed to completely fill the plurality of vertical openings 515 and the plurality of spaces SP2. In some embodiments, the channel material 313 may include doped polycrystalline silicon, doped polycrystalline germanium, or doped polycrystalline silicon germanium.

In some embodiments, the channel material 313 may include a semiconductor oxide (also referred to herein as an “oxide semiconductor” or “oxide semiconductor material”). The semiconductor oxide may include any suitable composition; and in some embodiments may include one or more of indium, zinc, tin and gallium. Examples of oxide semiconductor materials and/or compositions, as used herein, including one or more of indium, zinc, tin and gallium may include such materials as ZnOₓ, SnO₂, ZnₓO_{y}N, MgₓZn_{y}O_{z}, InₓZn_{y}O_{z}, InₓZn_{y}O_{z}, InₓGa_{y}Zn_{z}Oₐ, InₓGa_{y}Si_{z}Oₐ, ZrₓIn_{y}Zn_{z}Oₐ, HfₓIn_{y}Zn_{z}Oₐ, SnₓIn_{y}Zn_{z}Oₐ, AlₓSn_{y}In_{z}ZnₐO_{b}, SiₓIn_{y}Zn_{z}Oₐ, ZnₓSn_{y}O_{z}, AlₓZn_{y}Sn_{z}Oₐ, GaₓZn_{y}Sn_{z}Oₐ, and ZrₓZn_{y}Sn_{z}Oₐ.

In some embodiments, the channel material 313 may include a two-dimensional (2D) material. The 2D material may include any suitable composition; and in some embodiments may include one or more of a transition metal dichalcogenide, including molybdenum disulfide, molybdenum diselenide, molybdenum ditelluride, tungsten sulfide, and tungsten selenide. In some embodiments, the channel material 313 may be formed by, for example, atomic layer deposition or other applicable deposition processes.

In some embodiments, the channel material 313 may include a composite material such as an indium gallium zinc oxide material or indium zinc oxide material.

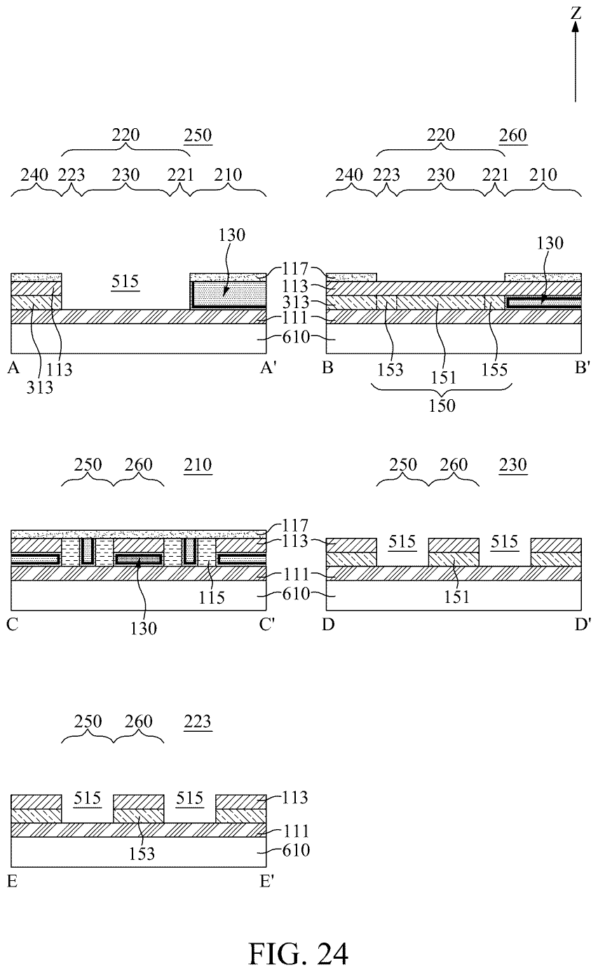

With reference to FIG. 24, an etching process (also referred to as the second channel-exposing etching process) may be performed to remove the channel material 313 at the overlapping areas between the channel region 220 and the plurality of isolation regions 250. The channel material 313 formed on the node-capping layer 117 may also be removed during the second channel-exposing etching process. In some embodiments, the second channel-exposing etching process may be an anisotropic etching process.

The remaining channel material 313 at the overlapping areas between the channel region 220 and the plurality of active regions 260 may be referred to as the plurality of channel layers 150. Each channel layer 150 may be parallel to the top surface 610TS of the supporting substrate 610 and extend along the Y direction. Each channel layer 150 may include a channel 151, a source 153, and a drain 155. The channel 151 may be at the overlapping areas between the word line region 230 and the active region 260. The source 153 and the drain 155 may be at two ends of the channel 151 and opposite to each other. The drain 155 may be at the overlapping area between the first source/drain region 221 and the active region 260. The drain 155 may be disposed between the channel 151 and the storage node structure 130 and may contact the storage node structure 130. The source 153 may be at the overlapping area between the second source/drain region 223 and the active region 260.

With reference to FIG. 1 and FIGS. 25 and 26, at step S17, a plurality of interface insulating layers 159 may be conformally formed to cover the plurality of channel layers 150, and a first thermal treatment may be performed.

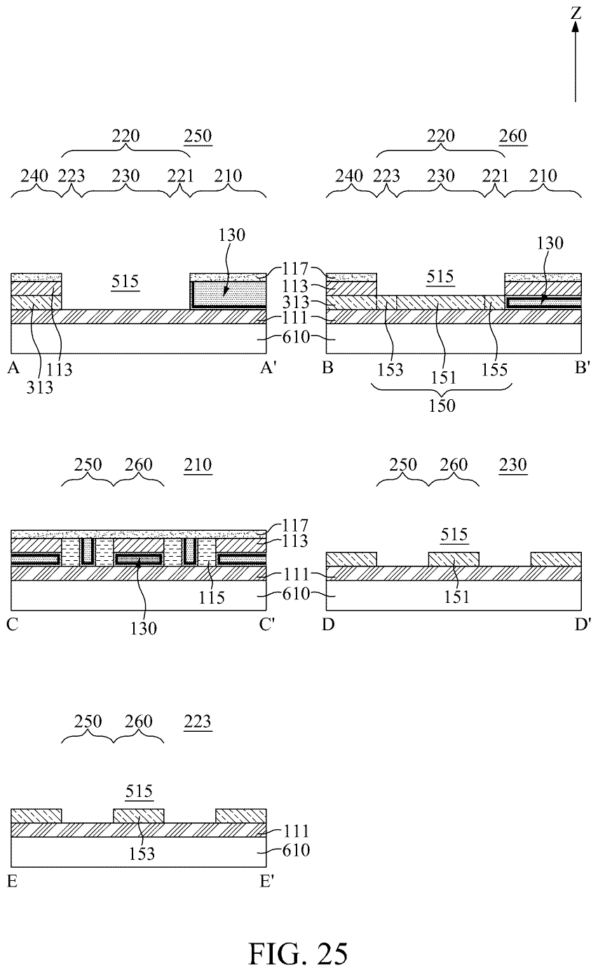

With reference to FIG. 25, the top dielectric layer 113 within the channel region 220 may be removed by an etching process (also referred to as the third channel-exposing etching process). In some embodiments, the third channel-exposing etching process may be an anisotropic etching process. The channel layer 150 may be exposed through the vertical opening 515 after the third channel-exposing etching process.

In some embodiments, the bottom stop layer 111 may also be removed during the third channel-exposing etching process. In such a situation, the bottom surface of the channel layer 150 may also be exposed.

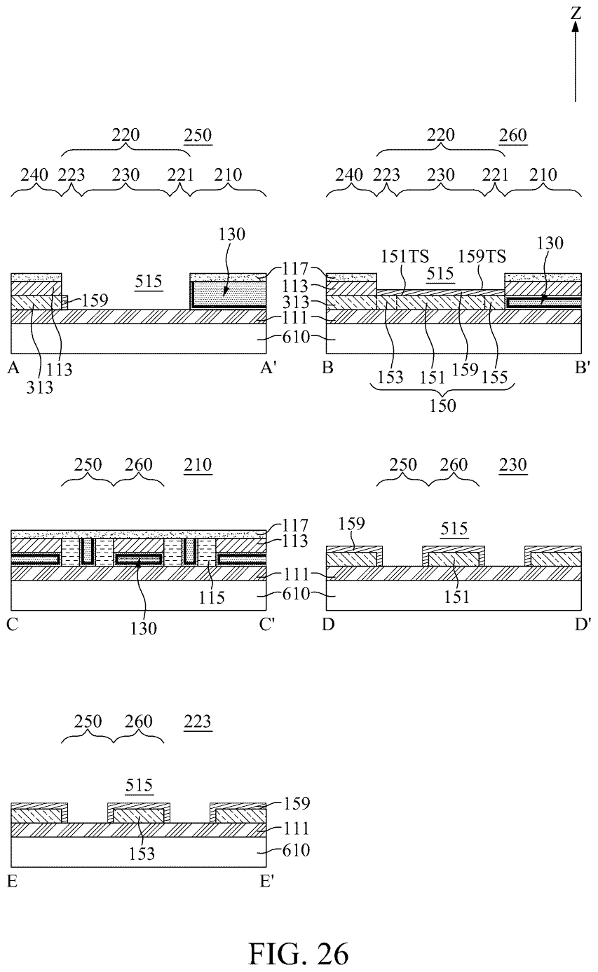

With reference to FIG. 26, an oxidation process may be performed to form the interface insulating layer 159 covering the channel layer 150 and exposed channel material 313. In some embodiments, the oxidation process may be performed at a temperature lying in the range of about 700° C. to about 1100° C. In some embodiments, the oxidation process may be performed by utilizing a dry technique or by a wet technique. In the dry technique, the oxidation step may be performed, for example, by heating the intermediate semiconductor device illustrated in FIG. 25 under gaseous oxygen. In the wet technique, the oxidation process may be performed, for example, by heating the intermediate semiconductor device illustrated in FIG. 25 in an atmosphere charged with steam. In some embodiments, in both the dry technique and the wet technique, the oxidizing atmosphere may also be charged with hydrochloric acid.

In some embodiments, the first thermal treatment may be performed after the formation of the interface insulating layer 159. In some embodiments, first thermal treatment may be performed at a temperature higher than 1000° C., or about 1100° C. and about 1200° C. In some embodiments, the first thermal treatment may be performed under a non-oxidizing atmosphere, which may comprise argon, nitrogen, hydrogen, or a mixture of these gases. In some embodiments, the first thermal treatment may be performed in a vacuum.

In some embodiments, the first thermal treatment may be a rapid thermal annealing process. In some embodiments, the rapid thermal annealing process may be performed at a temperature between about 1000° C. and about 1400° C. or between about 1100° C. and about 1250° C. In some embodiments, the rapid thermal annealing process may be performed for about 1 second to about 60 seconds. In some embodiments, the rapid thermal annealing process may be performed under an atmosphere of a pure selected gas. In some embodiments, the pure selected gas may be a noble gas. In some embodiments, the pure selected gas may be argon.

After the first thermal treatment, the surface roughness (or interface roughness) of the channel layer 150 (or the interface insulating layer 159) may be improved. For example, the top surface 151TS (or surface) of the channel layer 150 may not deviate by more than three times its root mean square roughness, by more than two times its root mean square roughness, or by more than one time its root mean square roughness. The top surface 159TS (or surface) of the interface insulating layer 159 may not deviate by more than three times its root mean square roughness, by more than two times its root mean square roughness, or by more than one time its root mean square roughness.

In some embodiments, the first thermal treatment may be performed before the formation of the interface insulating layer 159.

It should be noted that the interface insulating layer 159 may be not shown in top-view diagrams for clarity.

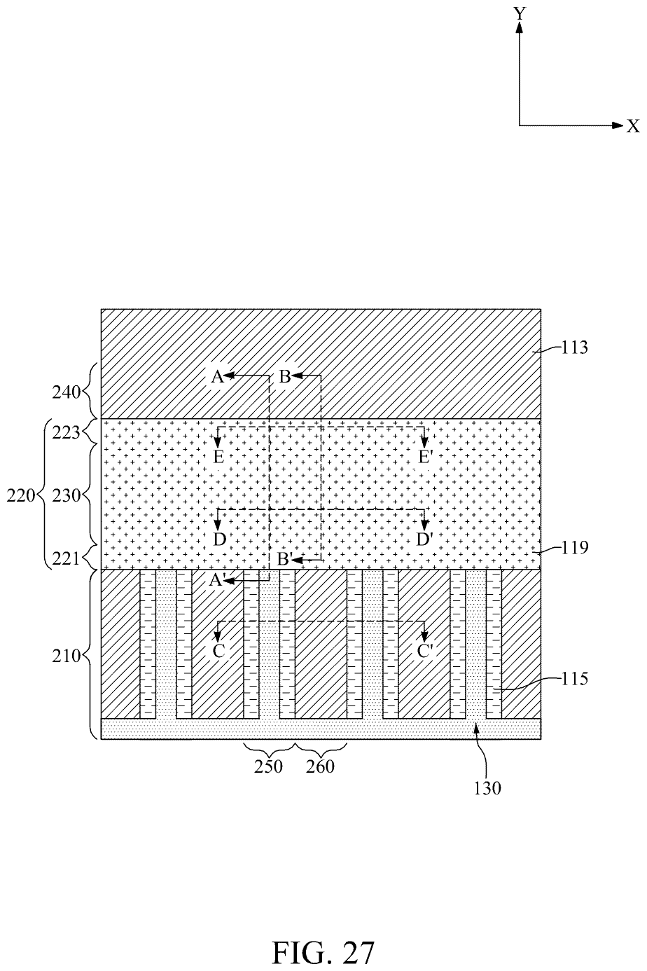

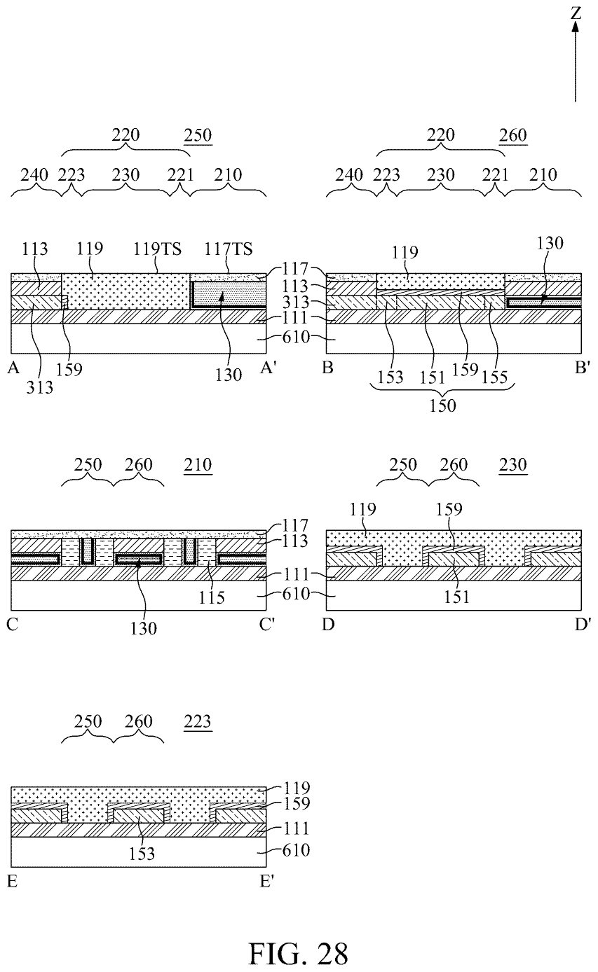

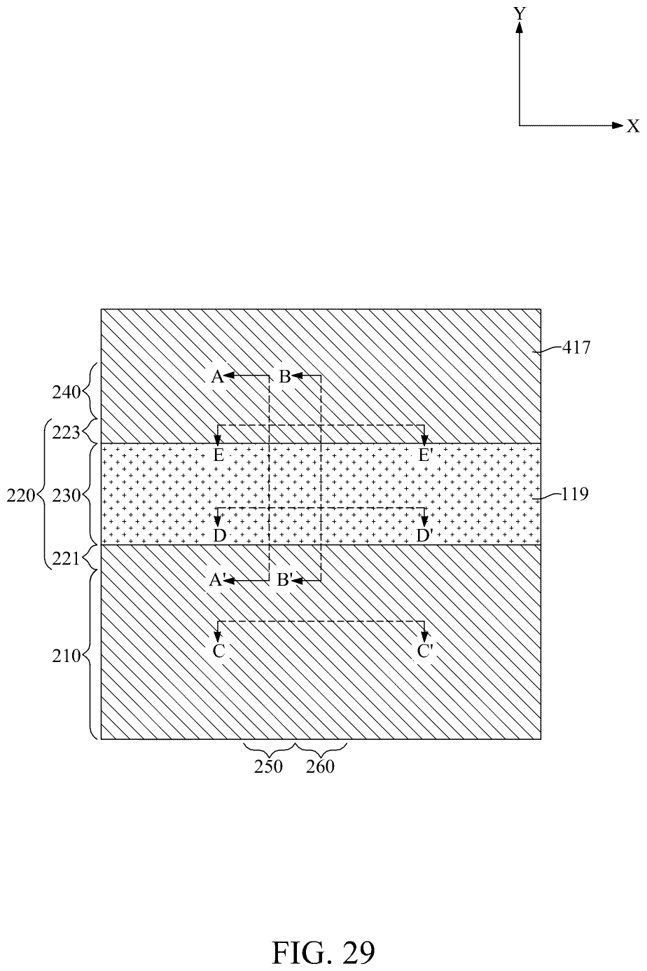

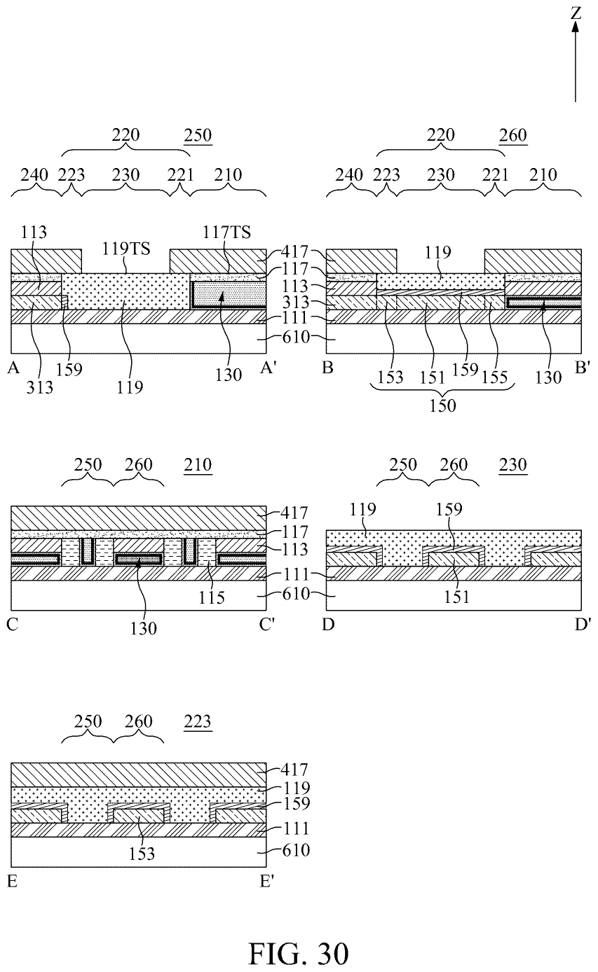

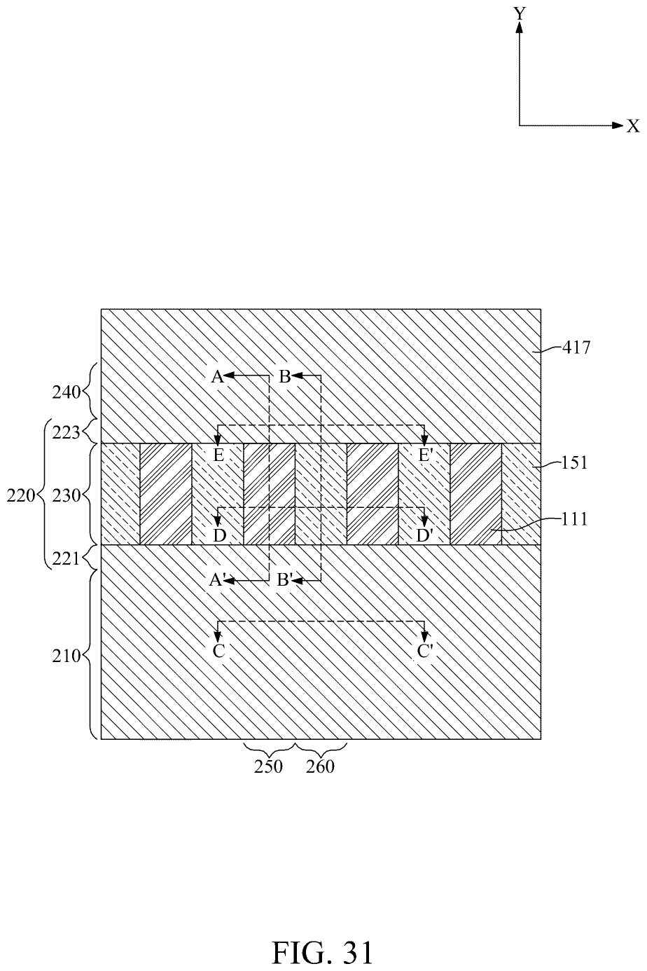

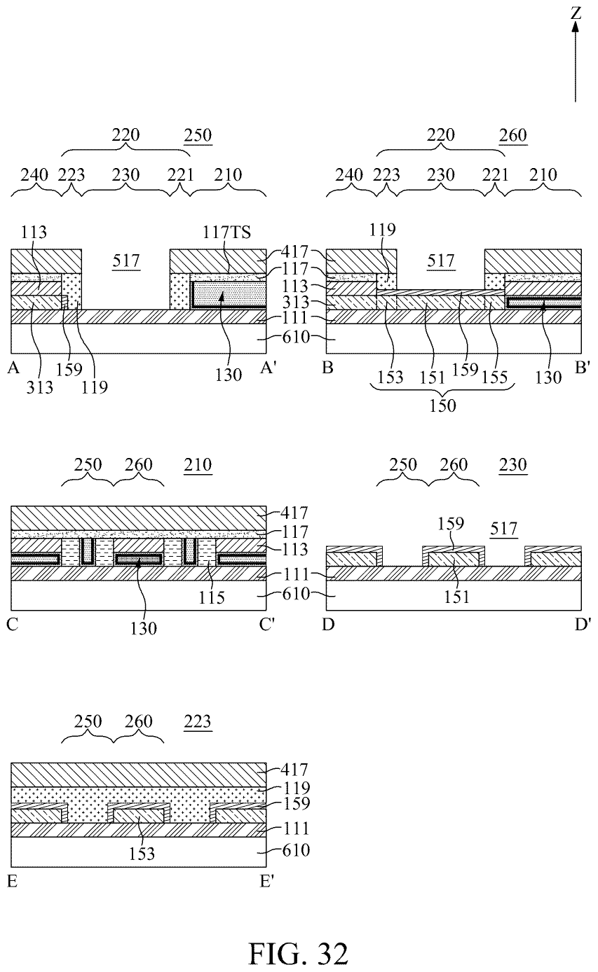

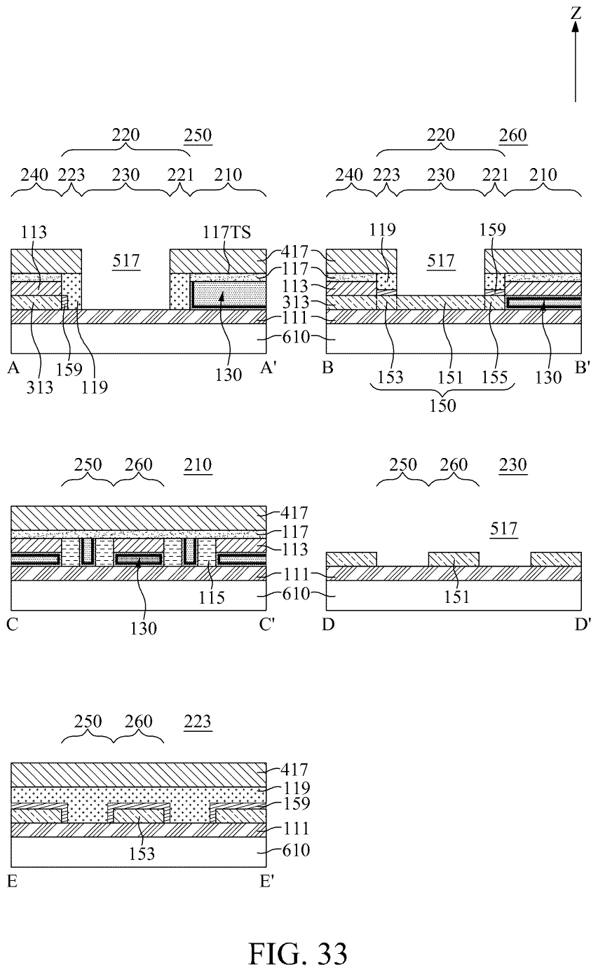

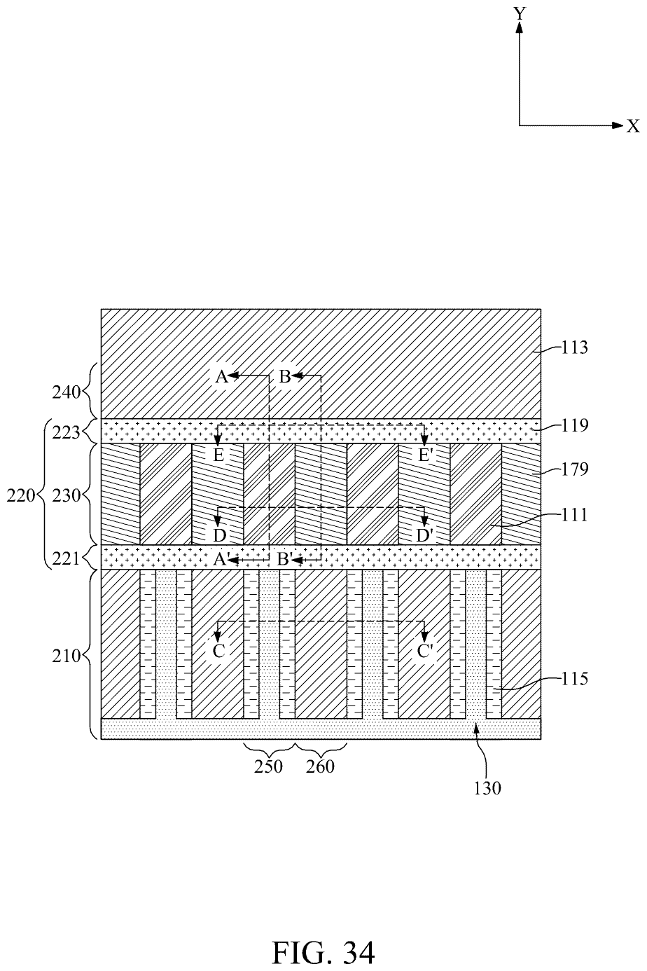

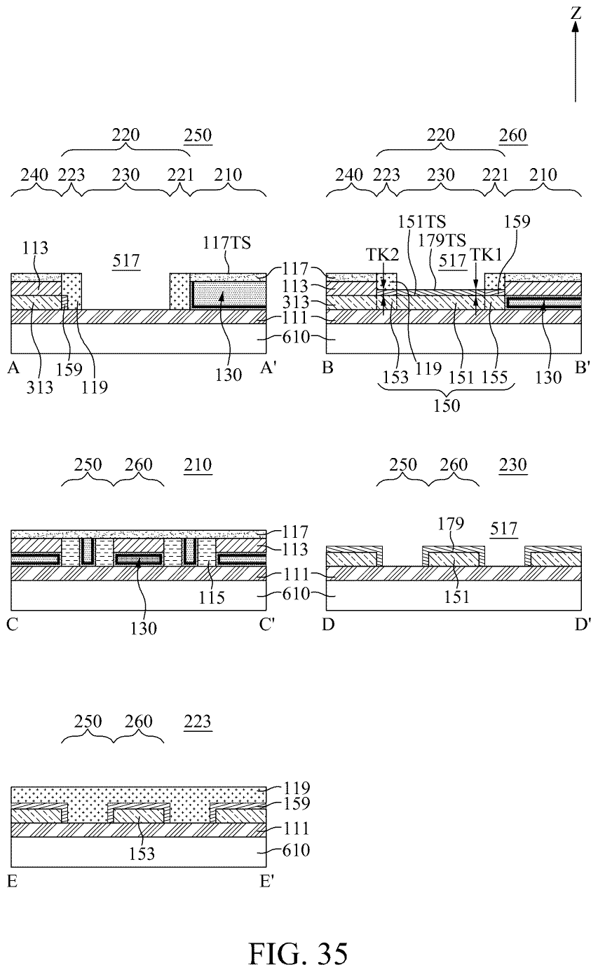

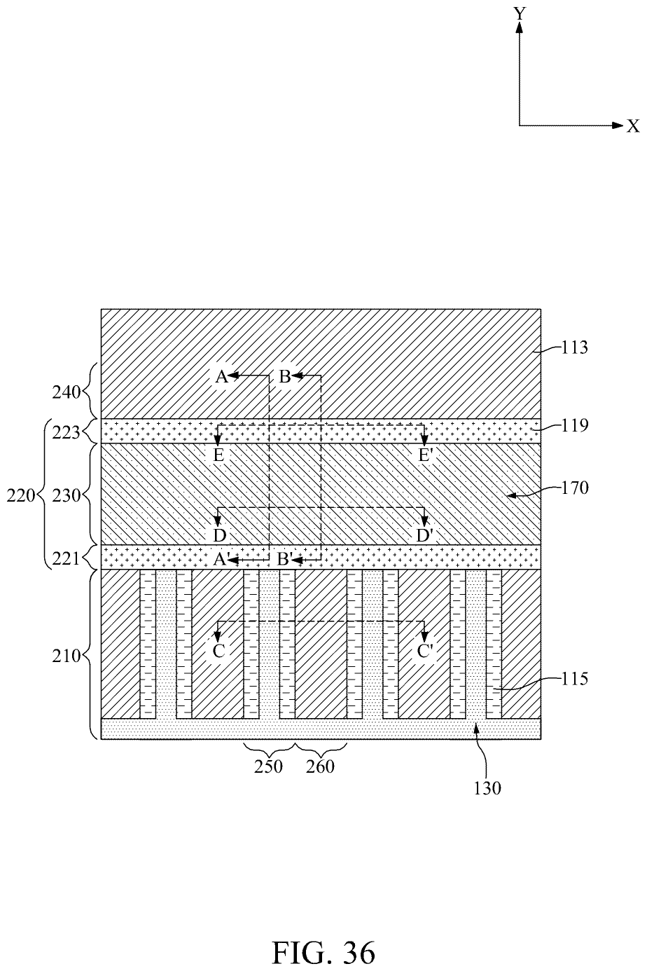

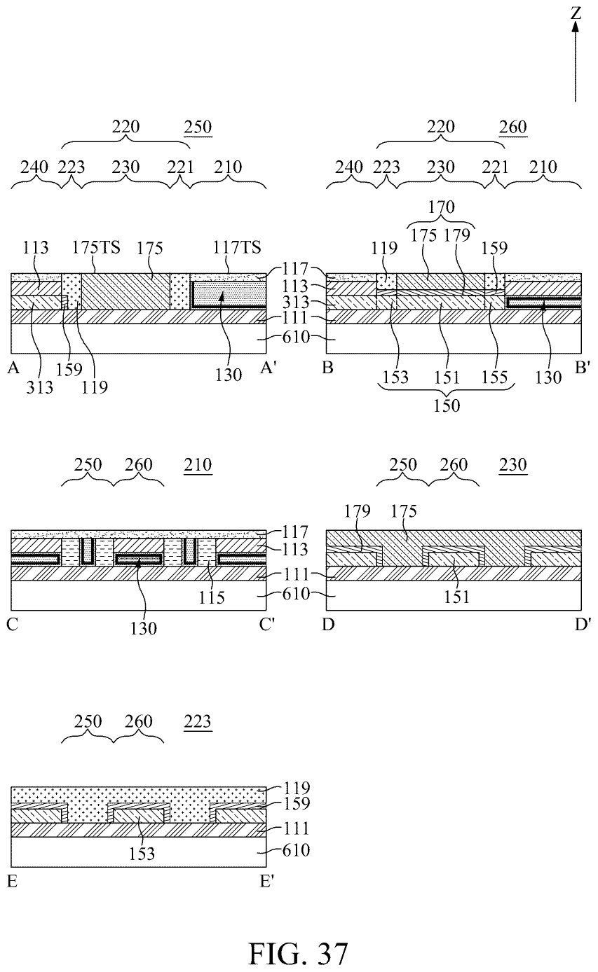

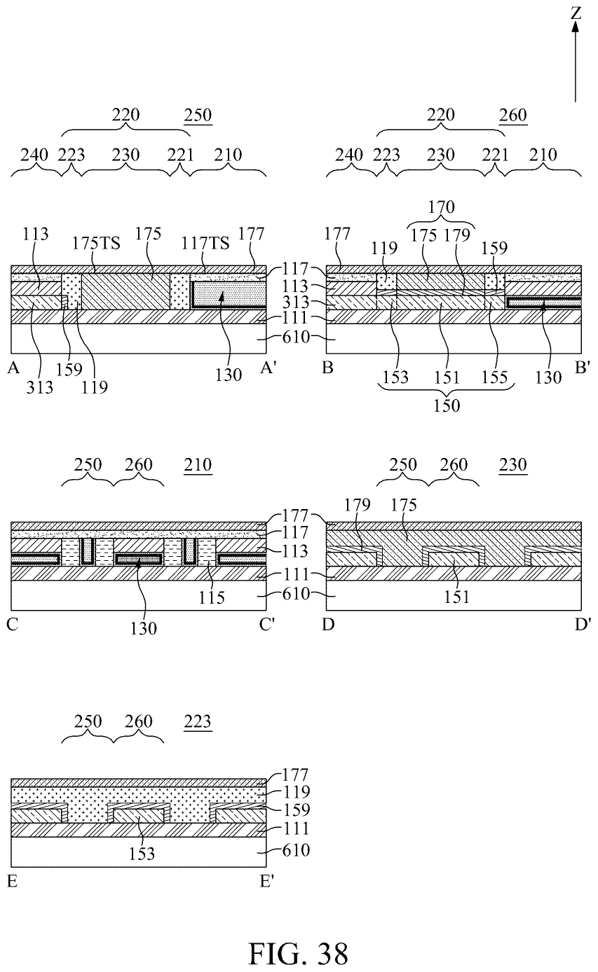

FIG. 27 illustrates, in a schematic top-view diagram, an intermediate semiconductor device in accordance with one embodiment of the present disclosure. FIG. 28 is a schematic cross-sectional view diagram taken along lines A-A′, B-B′, C-C′, D-D′, and E-E′ in FIG. 27. FIG. 29 illustrates, in a schematic top-view diagram, an intermediate semiconductor device in accordance with one embodiment of the present disclosure. FIG. 30 is a schematic cross-sectional view diagram taken along lines A-A′, B-B′, C-C′, D-D′, and E-E′ in FIG. 29. FIG. 31 illustrates, in a schematic top-view diagram, an intermediate semiconductor device in accordance with one embodiment of the present disclosure. FIGS. 32 and 33 are schematic cross-sectional view diagrams taken along lines A-A′, B-B′, C-C′, D-D′, and E-E′ in FIG. 31 illustrating part of the flow for fabricating the semiconductor device 1A in accordance with one embodiment of the present disclosure. FIG. 34 illustrates, in a schematic top-view diagram, an intermediate semiconductor device in accordance with one embodiment of the present disclosure. FIG. 35 is a schematic cross-sectional view diagram taken along lines A-A′, B-B′, C-C′, D-D′, and E-E′ in FIG. 34. FIG. 36 illustrates, in a schematic top-view diagram, an intermediate semiconductor device in accordance with one embodiment of the present disclosure. FIGS. 37 and 38 are schematic cross-sectional view diagrams taken along lines A-A′, B-B′, C-C′, D-D′, and E-E′ in FIG. 36 illustrating part of the flow for fabricating the semiconductor device 1A in accordance with one embodiment of the present disclosure.

With reference to FIG. 1 and FIGS. 27 to 38, at step S19, a plurality of channels 151 of the plurality of channel layers 150 may be exposed, a plurality of word line dielectric layers 179 may be conformally formed covering the plurality of channels 151, a second thermal treatment may be performed, a word line conductive layer 175 may be formed surrounding the plurality of word line dielectric layers 179 and configure a word line structure 170, and a word-line-capping layer 177 may be formed covering the word line structure 170.

With reference to FIGS. 27 and 28, a channel-filling dielectric layer 119 may be formed to completely fill the vertical opening 515. A planarization process, such as chemical mechanical polishing, may be performed until the top surface 117TS of the node-capping layer 117 is exposed to remove excess material and provide a substantially flat surface for subsequent processing steps. In some embodiments, the top surface 119TS of the channel-filling dielectric layer 119 and the top surface 117TS of the node-capping layer 117 may be substantially coplanar. In some embodiments, the channel-filling dielectric layer 119 may be formed of a material having etching selectivity to the interface insulating layer 159. In some embodiments, the channel-filling dielectric layer 119 may be formed of a material having etching selectivity to the top dielectric layer 113. In some embodiments, the channel-filling dielectric layer 119 may be formed of a material having etching selectivity to the bottom stop layer 111. In some embodiments, the channel-filling dielectric layer 119 may be formed of a material having etching selectivity to the channel material 313. In some embodiments, the channel-filling dielectric layer 119 may be formed of, for example, silicon oxide, silicon nitride, silicon carbonitride, silicon oxycarbide, or other applicable insulating material. In some embodiments, the channel-filling dielectric layer 119 may be formed by, for example, chemical vapor deposition, plasma-enhanced chemical vapor deposition, atomic layer deposition, or other applicable deposition processes.

With reference to FIGS. 29 and 30, a word-line-exposing mask 417 may be formed on the node-capping layer 117 and the channel-filling dielectric layer 119. In some embodiments, the word-line-exposing mask 417 may be a photoresist layer. The word-line-exposing mask 417 may include a pattern which completely exposes the word line region 230. The first source/drain region 221, the second source/drain region 223, the storage node region 210, and the bit line region 240 may remain masked.

With reference to FIGS. 31 and 32, a vertical opening 517 may be formed by removing the exposed channel-filling dielectric layer 119 using an etching process. The interface insulating layer 159 within the word line region 230 may be exposed through the vertical opening 517. In some embodiments, the etching process may be an anisotropic etching process.

With reference to FIG. 33, the interface insulating layer 159 within the word line region 230 may be selectively removed using an etching process. The channel 151 may be exposed through the vertical opening 517 after the removal of the interface insulating layer 159. The source 153 and the drain 155 may still be covered by the interface insulating layer 159. In some embodiments, the etching process may be an anisotropic etching process. After the exposure of the channel 151, the word-line-exposing mask 417 may be removed.

In some embodiments, the bottom stop layer 111 within the word line region 230 may be also removed to expose the bottom surface 151BS of the channel 151.

With reference to FIGS. 34 and 35, the word line dielectric layer 179 may be conformally formed covering the channel 151. In some embodiments, the word line dielectric layer 179 may be formed by an oxidation process. In some embodiments, the oxidation process may be performed at a temperature lying in the range of about 700° C. to about 1100° C. In some embodiments, the oxidation process may be performed by utilizing a dry technique or by a wet technique. In the dry technique, the oxidation step may be performed, for example, by heating the intermediate semiconductor device illustrated in FIG. 33 under gaseous oxygen. In the wet technique, the oxidation process may be performed, for example, by heating the intermediate semiconductor device illustrated in FIG. 33 in an atmosphere charged with steam. In some embodiments, in both the dry technique and the wet technique, the oxidizing atmosphere may also be charged with hydrochloric acid.

In some embodiments, the thickness TK1 of the word line dielectric layer 179 and the thickness TK2 of the interface insulating layer 159 may be substantially the same. In some embodiments, the thickness TK1 of the word line dielectric layer 179 and the thickness TK2 of the interface insulating layer 159 may be different.

In some embodiments, the word line dielectric layer 179 and the interface insulating layer 159 may be formed of the same material. In some embodiments, the word line dielectric layer 179 and the interface insulating layer 159 may be formed of different materials. In some embodiments, the word line dielectric layer 179 may be formed by a deposition process such as atomic layer deposition. In some embodiments, the word line dielectric layer 179 may include silicon oxide, a high-k dielectric material, or other applicable dielectric materials.

With reference to FIG. 35, the second thermal treatment may be performed. In some embodiments, the second thermal treatment may be performed at a temperature higher than 1000° C., or about 1100° C. and about 1200° C. In some embodiments, the second thermal treatment may be performed under a non-oxidizing atmosphere, which may comprise argon, nitrogen, hydrogen, etc., or indeed a mixture of these gases. In some embodiments, the second thermal treatment may be performed in a vacuum.

In some embodiments, the second thermal treatment may be a rapid thermal annealing process. In some embodiments, the rapid thermal annealing process may be performed at a temperature of between about 1000° C. and about 1400° C. or between about 1100° C. and about 1250° C. In some embodiments, the rapid thermal annealing process may be performed for about 1 second to about 60 seconds. In some embodiments, the rapid thermal annealing process may be performed under an atmosphere of a pure selected gas. In some embodiments, the pure selected gas may be a noble gas. In some embodiments, the pure selected gas may be argon.

After the second thermal treatment, the surface roughness of the channel 151 (or the word line dielectric layer 179) may be improved. For example, the top surface 151TS (or surface) of the channel 151 may not deviate by more than three times its root mean square roughness, by more than two times its root mean square roughness, or by more than one time its root mean square roughness. The top surface 179TS (or surface) of the word line dielectric layer 179 may not deviate by more than three times its root mean square roughness, by more than two times its root mean square roughness, or by more than one time its root mean square roughness.

In some embodiments, the second thermal treatment may be performed before the formation of the word line dielectric layer 179.

With reference to FIGS. 36 and 37, the word line conductive layer 175 may be formed to completely fill the vertical opening 517 and cover the word line dielectric layer 179. A planarization process, such as chemical mechanical polishing, may be subsequently performed until the top surface 117TS of the node-capping layer 117 is exposed to remove excess material and provide a substantially flat surface for subsequent processing steps. In some embodiments, the top surface 175TS of the word line conductive layer 175 and the top surface 117TS of the node-capping layer 117 may be substantially coplanar. In some embodiments, the word line conductive layer 175 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

The plurality of word line dielectric layers 179 and the word line conductive layer 175 together configure the word line structure 170. The word line structure 170 may be at the word line region 230 and along the X direction.

With reference to FIG. 38, the word-line-capping layer 177 may be formed on the word line structure 170, the node-capping layer 117, and the channel-filling dielectric layer 119. In some embodiments, the word-line-capping layer 177 may be formed of, for example, silicon nitride, silicon oxide, silicon carbonitride, silicon oxycarbide, or other applicable insulating material. In some embodiments, the word-line-capping layer 177 may be formed by, for example, chemical vapor deposition, plasma-enhanced chemical vapor deposition, atomic layer deposition, or other applicable deposition processes.

It should be noted that the word-line-capping layer 177 is not shown in top-view diagrams for clarity.

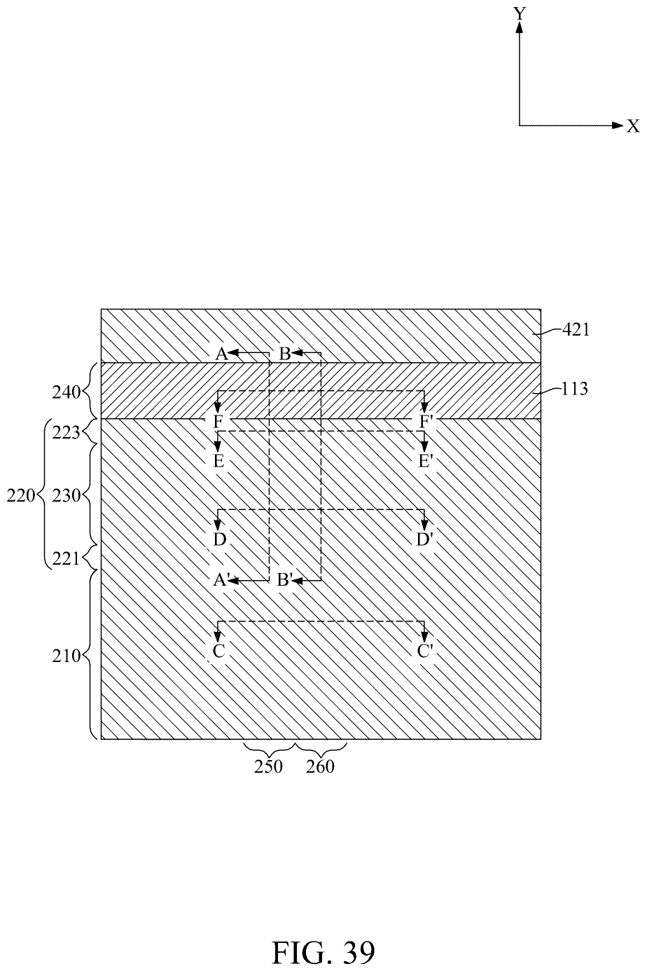

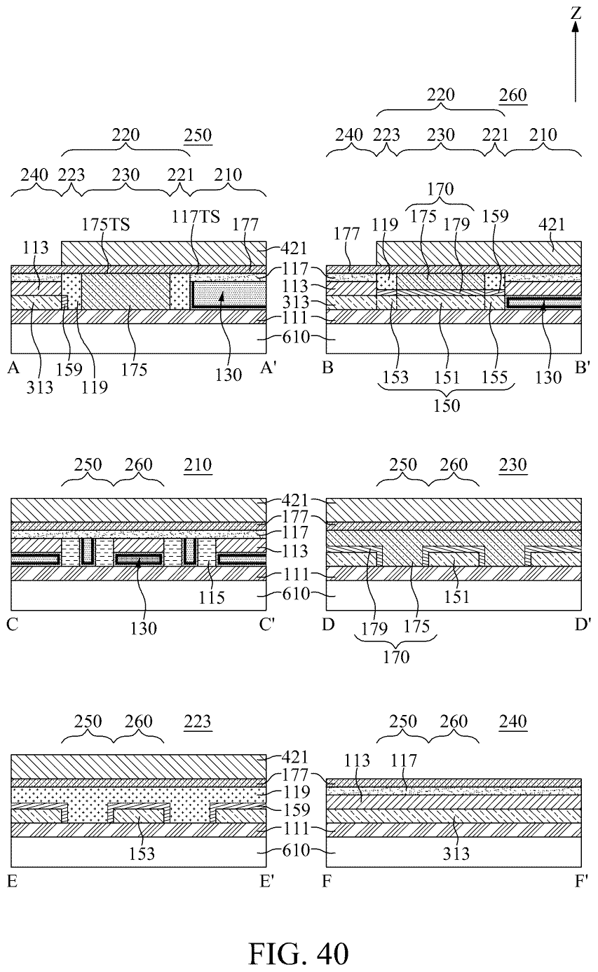

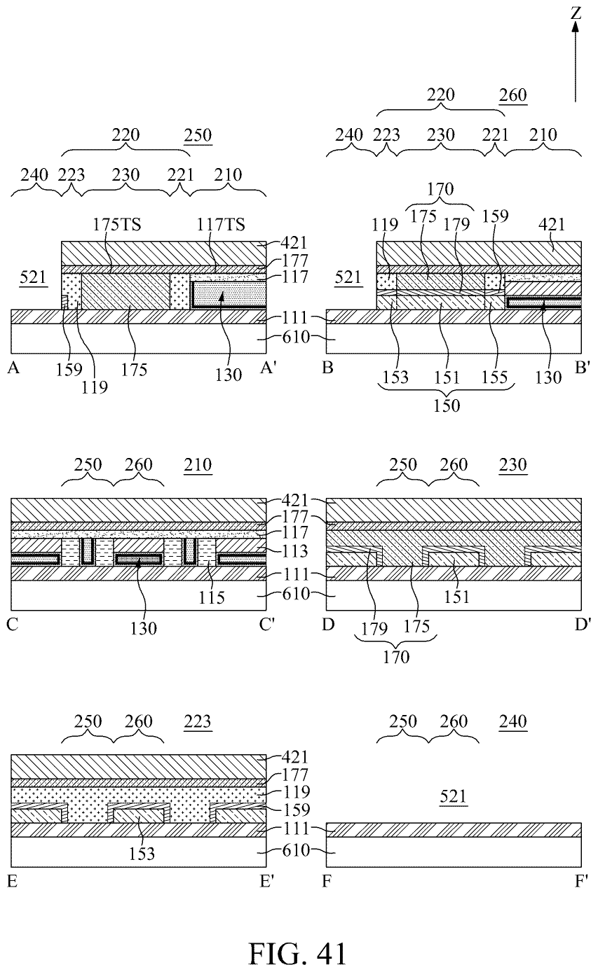

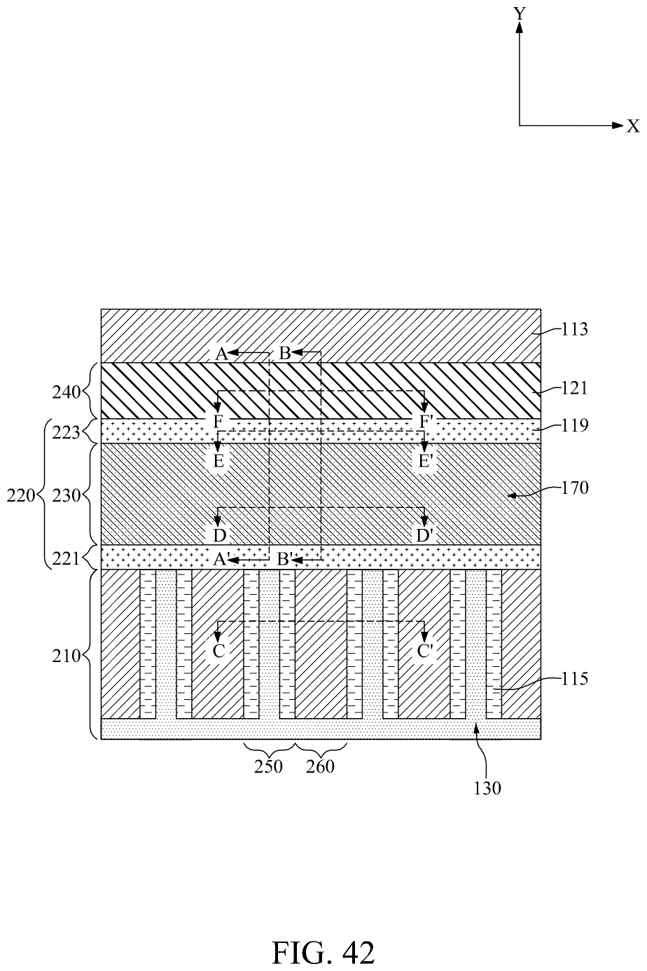

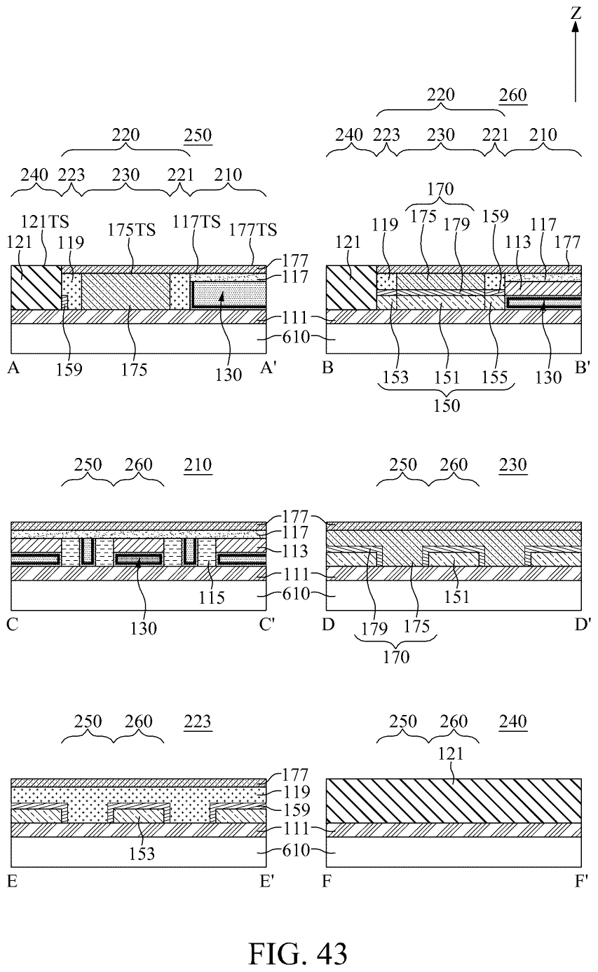

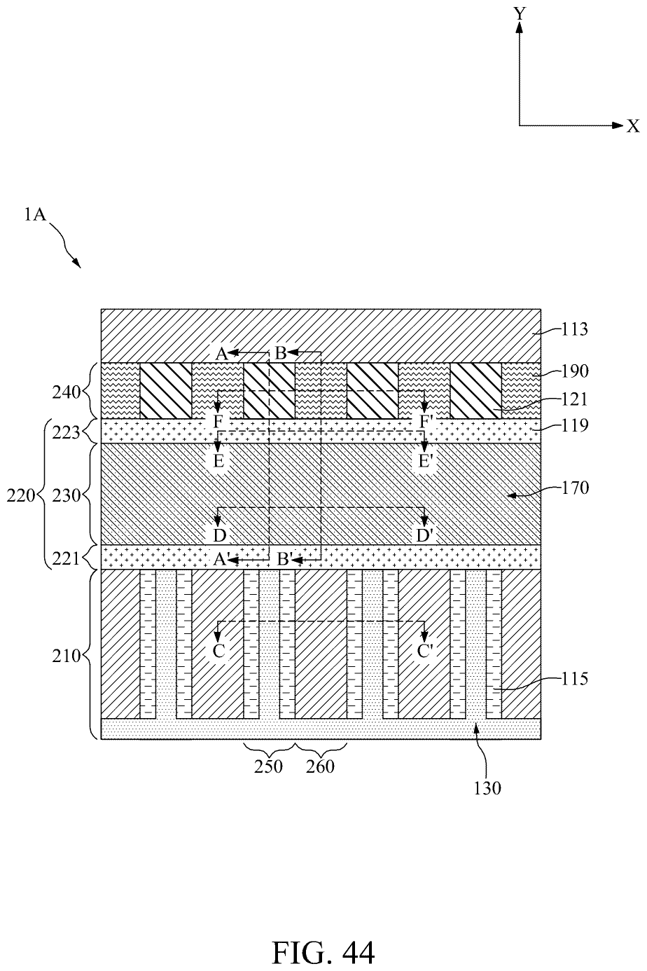

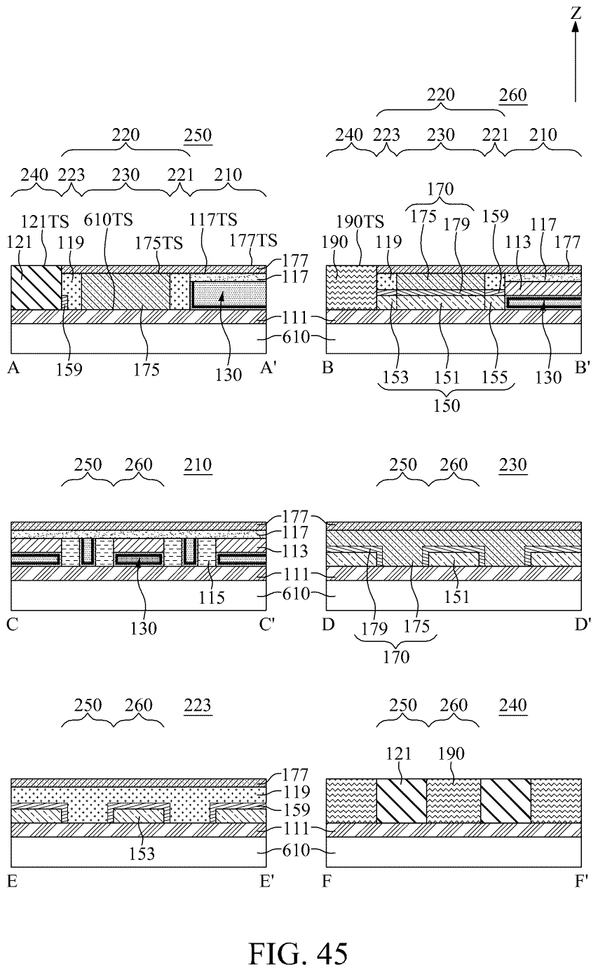

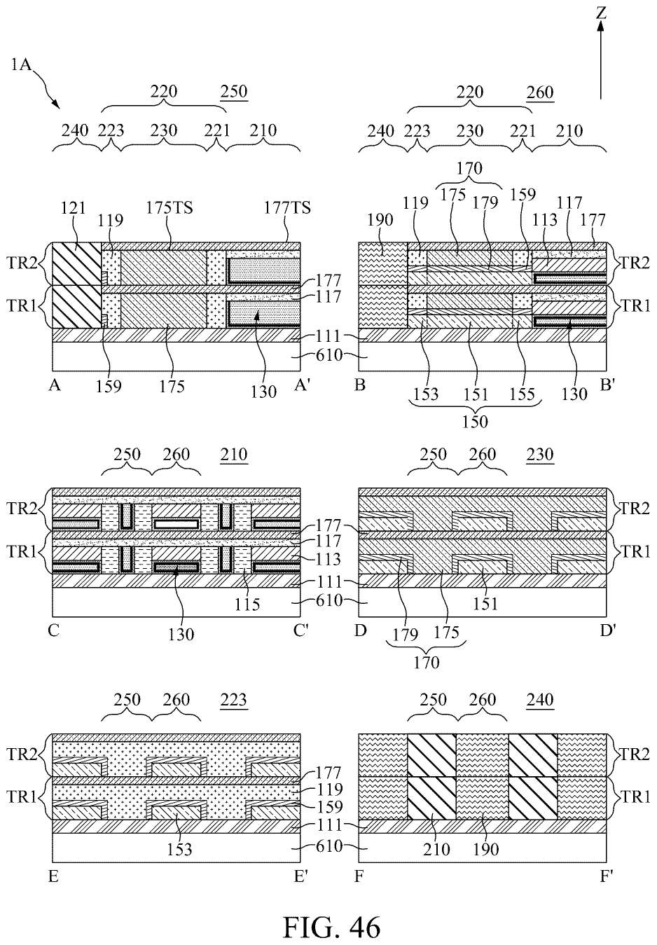

FIG. 39 illustrates, in a schematic top-view diagram, an intermediate semiconductor device in accordance with one embodiment of the present disclosure. FIGS. 40 and 41 are schematic cross-sectional view diagrams taken along lines A-A′, B-B′, C-C′, D-D′, E-E′, and F-F′ in FIG. 39 illustrating part of the flow for fabricating the semiconductor device 1A in accordance with one embodiment of the present disclosure. FIG. 42 illustrates, in a schematic top-view diagram, an intermediate semiconductor device in accordance with one embodiment of the present disclosure. FIG. 43 is a schematic cross-sectional view diagram taken along lines A-A′, B-B′, C-C′, D-D′, E-E′, and F-F′ in FIG. 42. FIG. 44 illustrates, in a schematic top-view diagram, an intermediate semiconductor device in accordance with one embodiment of the present disclosure. FIGS. 45 and 46 are schematic cross-sectional view diagrams taken along lines A-A′, B-B′, C-C′, D-D′, E-E′, and F-F′ in FIG. 44 illustrating part of the flow for fabricating the semiconductor device 1A in accordance with one embodiment of the present disclosure.

With reference to FIG. 1 and FIGS. 39 to 46, at step S21, a plurality of bit lines 190 may be formed to electrically connect the plurality of sources 153 of the plurality of channel layers 150.

With reference to FIGS. 39 and 40, a bit-line-exposing mask 421 may be formed on the word-line-capping layer 177. In some embodiments, the bit-line-exposing mask 421 may be a photoresist layer and may include a pattern which exposes the bit line region 240.

With reference to FIG. 41, a vertical opening 521 may be formed in the bit line region 240 by an etching process to expose the bottom stop layer 111 (or the supporting substrate 610) within the bit line region 240. The source 153 at the overlapping area between the second source/drain region 223 and the active region 260 may be exposed through the vertical opening 521.

With reference to FIGS. 42 and 43, an inter-layer dielectric 121 may be formed to fill the vertical opening 521. A planarization process, such as chemical mechanical polishing, may be performed until the top surface 177TS of the word-line-capping layer 177 is exposed to remove excess material and provide a substantially flat surface for subsequent processing steps. The top surface 177TS of the word-line-capping layer 177 and the top surface 121TS of the inter-layer dielectric 121 may be substantially coplanar. In some embodiments, the inter-layer dielectric 121 may be formed of, for example, silicon nitride, silicon oxide, silicon carbonitride, silicon oxycarbide, or other applicable insulating material. In some embodiments, the inter-layer dielectric 121 may be formed by, for example, chemical vapor deposition, plasma-enhanced chemical vapor deposition, or other applicable deposition processes.

With reference to FIGS. 44 and 45, the plurality of bit lines 190 may be formed at the overlapping areas between the bit line region 240 and the plurality of active regions 260. The plurality of bit lines 190 may be formed by removing the inter-layer dielectric 121 within the overlapping areas between the bit line region 240 and the plurality of active regions 260 to form openings (not shown) exposing the bottom stop layer 111 (or the supporting substrate 610) at the overlapping areas aforementioned. A conductive material may be subsequently deposited to fill the openings. A planarization process, such as chemical mechanical polishing, may be performed until the top surface 177TS of the word-line-capping layer 177 is exposed to remove excess material and provide a substantially flat surface for subsequent processing steps. The top surface 190TS of the bit line 190 and the top surface 177TS of the word-line-capping layer 177 may be substantially coplanar. In some embodiments, the conductive material may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

With reference to FIG. 46, a first tier TR1 may be configured by the top dielectric layer 113, the storage node structure 130, the channel layer 150, the word line structure 170, the node-capping layer 117, the channel-filling dielectric layer 119, the word-line-capping layer 177, the inter-layer dielectric 121, and the bit line 190. A second tier TR2, identical in elements and configuration to the first tier TR1, may be formed on top of the first tier TR1 by following the procedure illustrated in FIGS. 2 to 46. By repeating this process, additional tiers can be constructed, resulting in the formation of a three-dimensional (3D) memory.

By employing the thermal treatments, the surface roughness (or interface roughness) of the channel layer 150 may be improved and the stress of channel layer 150 may be reduced. As a result, the performance of the semiconductor device 1A may be improved.

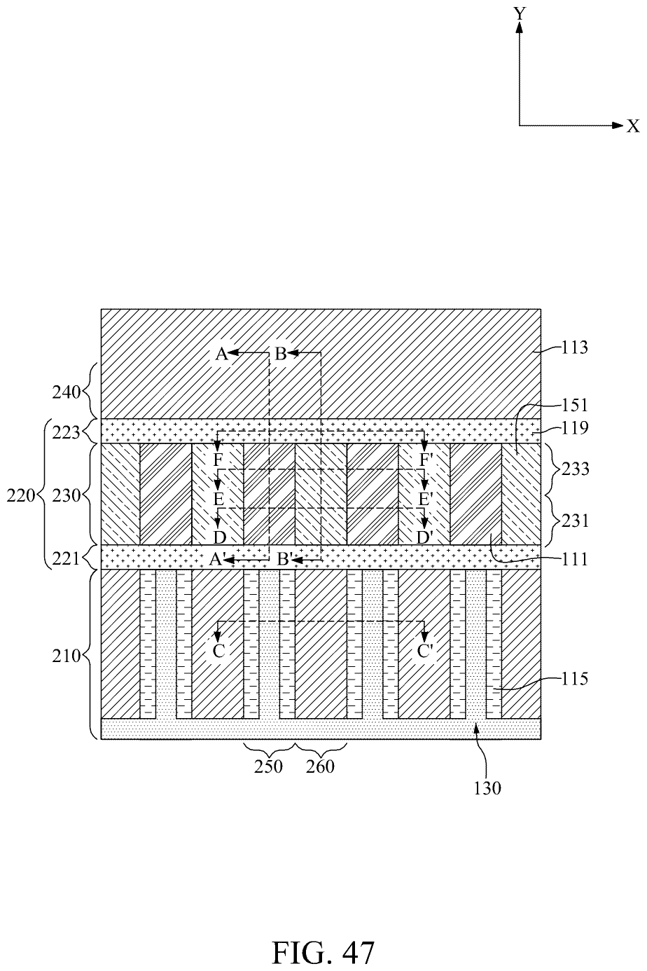

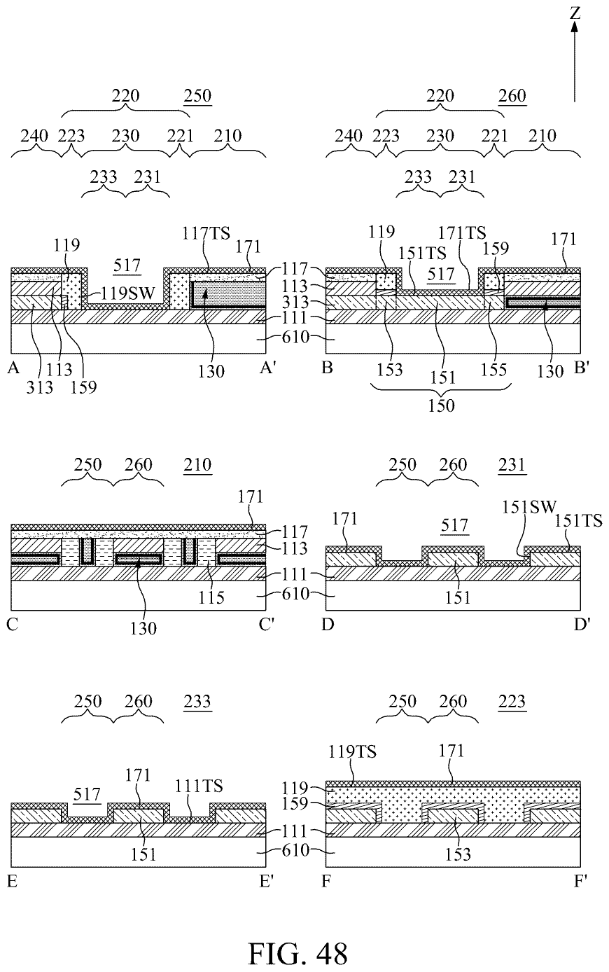

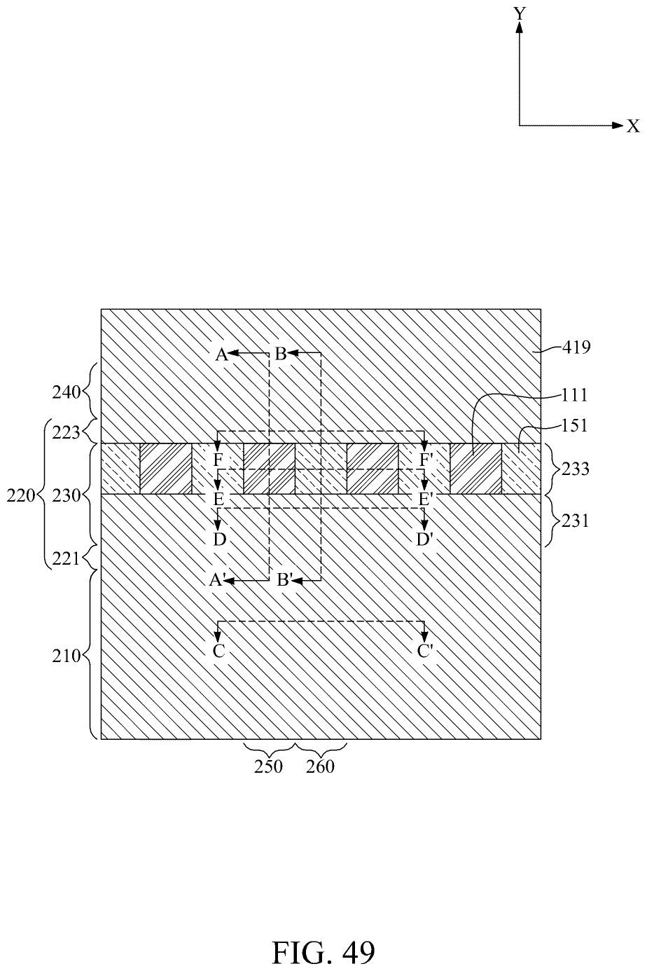

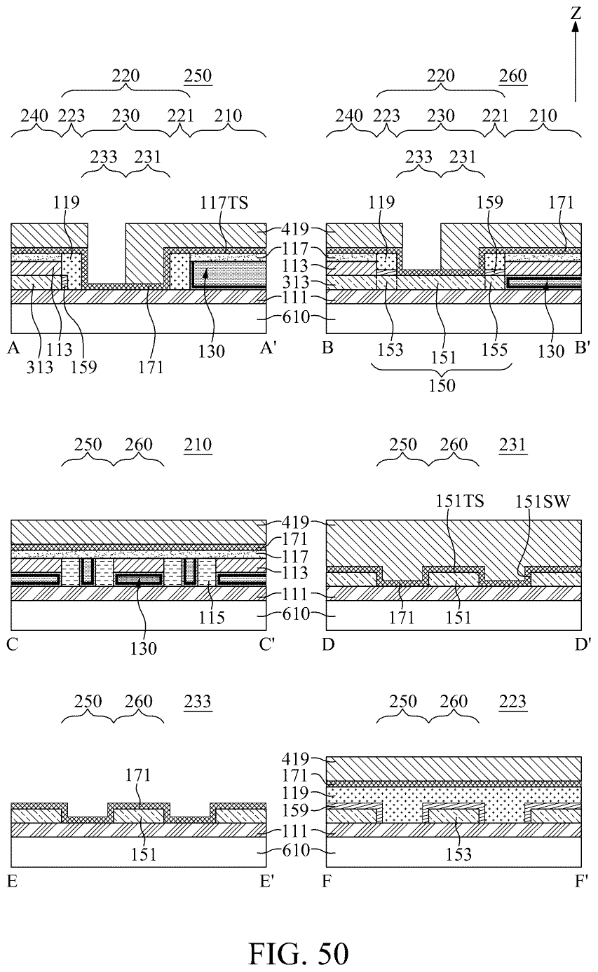

FIG. 47 illustrates, in a schematic top-view diagram, an intermediate semiconductor device in accordance with another embodiment of the present disclosure. FIG. 48 is a schematic cross-sectional view diagram taken along lines A-A′, B-B′, C-C′, D-D′, E-E′, and F-F′ in FIG. 47. FIG. 49 illustrates, in a schematic top-view diagram, an intermediate semiconductor device in accordance with another embodiment of the present disclosure. FIGS. 50 to 54 are schematic cross-sectional view diagrams taken along lines A-A′, B-B′, C-C′, D-D′, E-E′, and F-F′ in FIG. 49 illustrating part of a flow for fabricating a semiconductor device 1B in accordance with another embodiment of the present disclosure.

With reference to FIGS. 47 and 48, an intermediate semiconductor device may be fabricated with a procedure similar to that illustrated in FIGS. 2 to 33. The word line region 230 may include, in sequence along the Y direction, a first region 231 and a second region 233. An inner word line dielectric layer 171 may be conformally formed on the top surface 117TS of the node-capping layer 117, the top surface 119TS and sidewalls 119SW of the channel-filling dielectric layer 119, the top surface 111TS of the bottom stop layer 111, and the top surface 151TS and sidewall 151SW of the channel 151. In some embodiments, the inner word line dielectric layer 171 may be formed of, for example, a high-k dielectric material, silicon oxide, silicon nitride, silicon oxynitride, or a combination thereof. The high-k dielectric material may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate. In some embodiments, the inner word line dielectric layer 171 may be formed by, for example, atomic layer deposition.

It should be noted that the inner word line dielectric layer 171 is not shown in top-view diagrams for clarity.

In some embodiments, a thermal treatment (also referred to as the third thermal treatment) may be performed after the formation of the inner word line dielectric layer 171 with a procedure similar to the second thermal treatment illustrated in FIG. 35, and descriptions thereof are not repeated herein. After the thermal treatment, the surface roughness of the channel layer 150 (or the inner word line dielectric layer 171) may be improved. For example, the top surface 171TS (or surface) of the inner word line dielectric layer 171 may not deviate by more than three times its root mean square roughness, by more than two times its root mean square roughness, or by more than one time its root mean square roughness.

With reference to FIGS. 49 and 50, a region-exposing mask 419 may be formed over the intermediate semiconductor device illustrated in FIG. 48. In some embodiments, the region-exposing mask 419 may include a pattern which exposes the second region 233, which is adjacent to the second source/drain region 223, of the supporting substrate 610. Detailedly, the inner word line dielectric layer 171 within the second region 233 may be exposed. The first region 231, the first source/drain region 221, the second source/drain region 223, the storage node region 210, and the bit line region 240 may be masked.

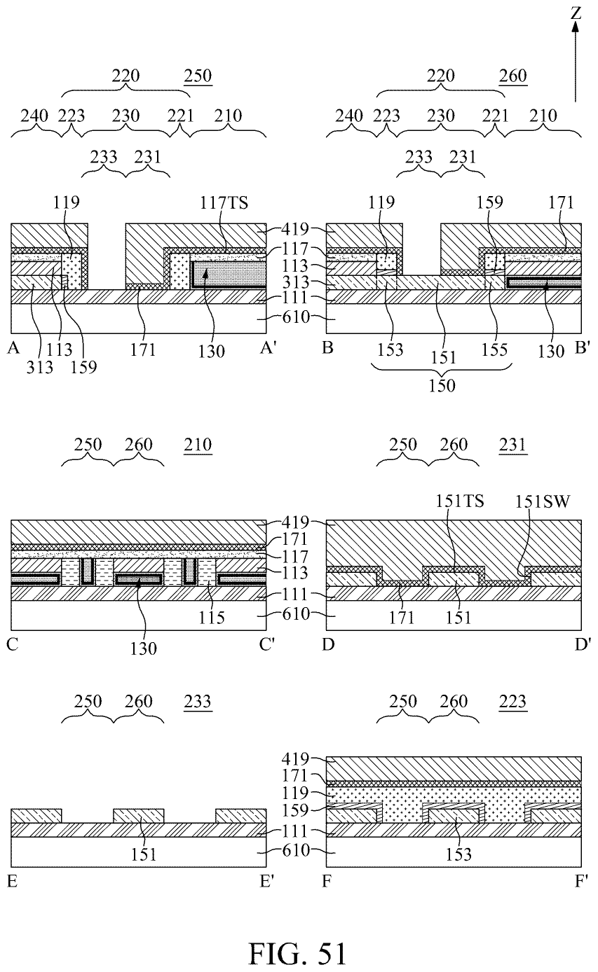

With reference to FIG. 51, an etching process may be performed to remove the exposed inner word line dielectric layer 171. The channel 151 within the second region 233 may be exposed after the etching process and the channel 151 within the first region 231 may remain covered by the inner word line dielectric layer 171. In some embodiments, the inner word line dielectric layer 171 formed on the sidewall 113SW of the top dielectric layer 113 and the sidewall 119SW of the channel-filling dielectric layer 119 may also be removed. In some embodiments, the etching process may be an anisotropic etching process. After the etching process, the region-exposing mask 419 may be removed.

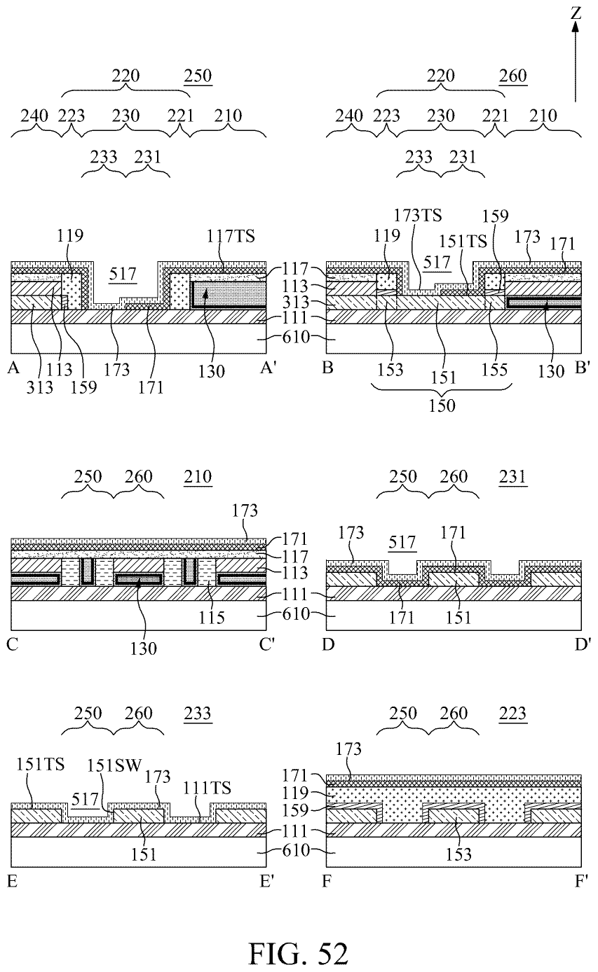

With reference to FIG. 52, the outer word line dielectric layer 173 may be conformally formed on the inner word line dielectric layer 171, the top surface 111TS of the bottom stop layer 111, and the top surface 151TS of the channel 151 within the second region 233. In some embodiments, the inner word line dielectric layer 171 and the outer word line dielectric layer 173 may be formed of the same material. In some embodiments, the inner word line dielectric layer 171 and the outer word line dielectric layer 173 may be formed of different materials. In some embodiments, the outer word line dielectric layer 173 may be formed of, for example, a high-k dielectric material, silicon oxide, silicon nitride, silicon oxynitride, or a combination thereof. In some embodiments, the outer word line dielectric layer 173 may be formed by, for example, atomic layer deposition.

Detailedly, after the deposition of the outer word line dielectric layer 173, the channel 151 within the second region 233 may be only covered by the outer word line dielectric layer 173, and the channel 151 within the first region 231 may be covered by a stack including the inner word line dielectric layer 171 (directly contacts the channel 151 within the first region 231) and the outer word line dielectric layer 173.

In some embodiments, a thermal treatment (also referred to as the fourth thermal treatment) may be performed after the formation of the outer word line dielectric layer 173 with a procedure similar to the second thermal treatment illustrated in FIG. 35, and descriptions thereof are not repeated herein. After the thermal treatment, the surface roughness of the channel layer 150 (or the outer word line dielectric layer 173) may be improved. For example, the top surface 173TS (or surface) of the outer word line dielectric layer 173 may not deviate by more than three times its root mean square roughness, by more than two times its root mean square roughness, or by more than one time its root mean square roughness.

It should be noted that the outer word line dielectric layer 173 is not shown in top-view diagrams for clarity.

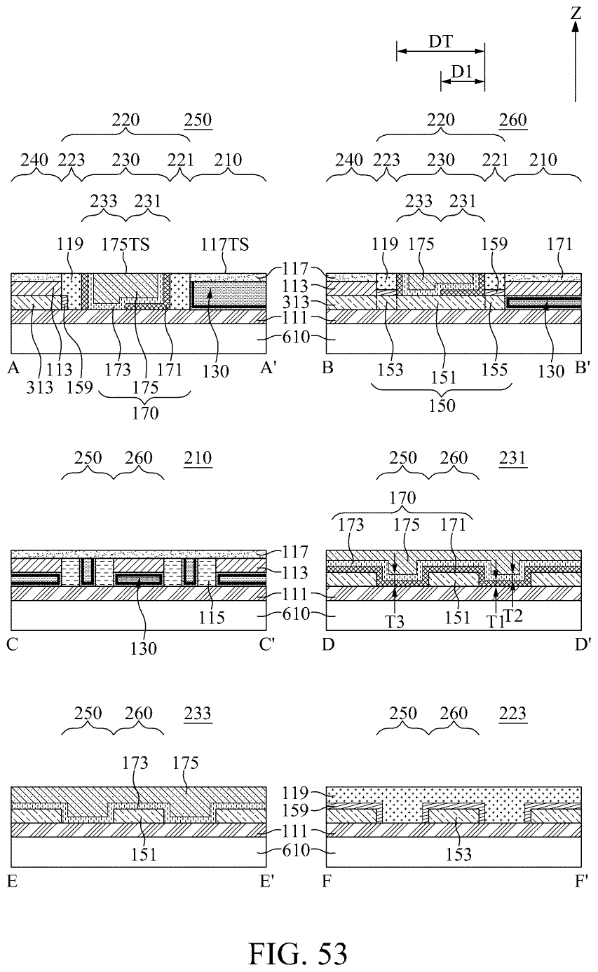

With reference to FIG. 53, the word line conductive layer 175 may be formed to completely fill the vertical opening 517 and cover the outer word line dielectric layer 173. A planarization process, such as chemical mechanical polishing, may be subsequently performed until the top surface 117TS of the node-capping layer 117 is exposed to remove excess material and provide a substantially flat surface for subsequent processing steps. State differently, the word line conductive layer 175 may surround the inner word line dielectric layer 171 and the outer word line dielectric layer 173, while directly contacting the outer word line dielectric layer 173. In some embodiments, the top surface 175TS of the word line conductive layer 175 and the top surface 117TS of the node-capping layer 117 may be substantially coplanar. In some embodiments, the word line conductive layer 175 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

The inner word line dielectric layer 171, the outer word line dielectric layer 173, and the word line conductive layer 175 together configure the word line structure 170. The word line structure 170 may be at the word line region 230 and along the X direction.

In some embodiments, the ratio of the dimension D1 (or length) of the first region 231 to the dimension DT of the word line region 230 (or the sum of the first region 231 and the second region 233) may be between about 0.15 and about 0.85, between about 0.20 and about 0.75, between about 0.30 and about 0.60, or about 0.50.

In some embodiments, the thickness T1 of the inner word line dielectric layer 171 and the thickness T2 of the outer word line dielectric layer 173 may be substantially the same. In some embodiments, thickness T1 of the inner word line dielectric layer 171 may be less than the thickness T2 of the outer word line dielectric layer 173. In some embodiments, the thickness T1 of the inner word line dielectric layer 171 may be greater than the thickness T2 of the outer word line dielectric layer 173.

In some embodiments, the ratio of the thickness T2 of the outer word line dielectric layer 173 to the thickness T3 of the stack of the inner word line dielectric layer 171 and the outer word line dielectric layer 173 may be between about 0.16 and about 0.50 or between about 0.20 to 0.45.

In some embodiments, the dielectric layer of the word line structure 170 may be referred to as a stepped dielectric due to the thickness difference between the outer word line dielectric layer 173 and the stack of the inner word line dielectric layer 171 and the outer word line dielectric layer 173.

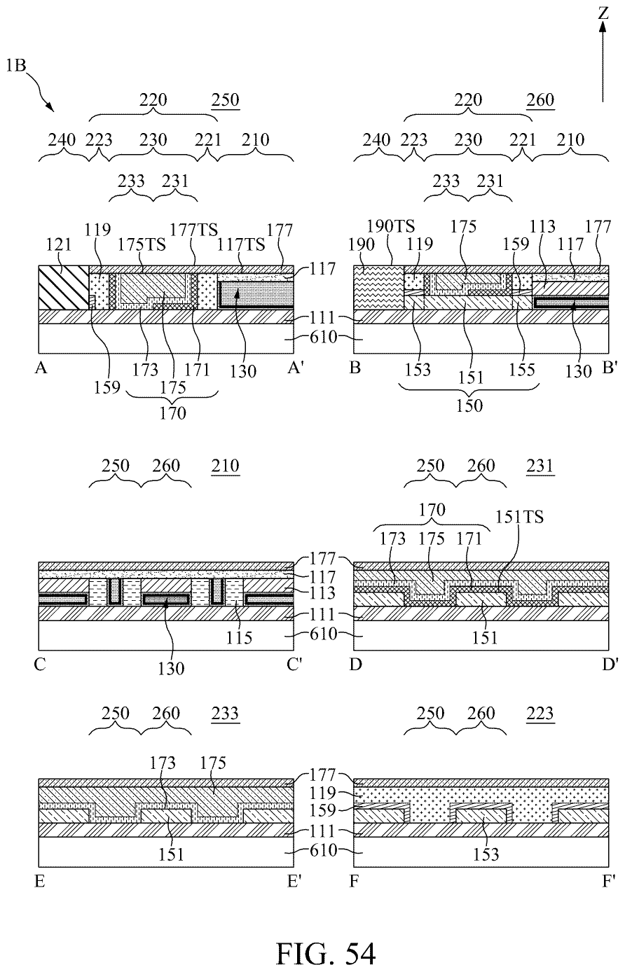

With reference to FIG. 54, the word-line-capping layer 177, the inter-layer dielectric 121, and the bit line 190 may be formed with a procedure similar to that illustrated in FIGS. 38 to 45, and descriptions thereof are not repeated herein.

By employing the thicker word line dielectric layer consisting of the inner word line dielectric layer 171 and the outer word line dielectric layer 173, the gate induced drain leakage may be reduced. As a result, the performance (such as retention time) of the semiconductor device 1B may be improved. Additionally, the outer word line dielectric layer 173 including the high-k dielectric material may improve drain current for the semiconductor device 1B.

One aspect of the present disclosure provides a semiconductor device including a supporting substrate; and a channel layer positioned parallel to a top surface of the supporting substrate, extending along a first direction, and including, in a sequence along the first direction, a drain, a channel, and a source. A top surface of the channel deviates less than three times its root mean square roughness.

Another aspect of the present disclosure provides a method for fabricating a semiconductor device including providing a supporting substrate; forming a channel layer parallel to a top surface of the supporting substrate, extending along a first direction, and including, in a sequence along the first direction, a drain, a channel, and a source; conformally forming an interface insulating layer covering the channel layer; and performing a first thermal treatment to the channel layer and the interface insulating layer. A top surface of the channel layer deviates less than three times its root mean square roughness.

Another aspect of the present disclosure provides a method for fabricating a semiconductor device including providing a supporting substrate; forming a channel layer parallel to a top surface of the supporting substrate, extending along a first direction, and including, in a sequence along the first direction, a drain, a channel, and a source; conformally forming a word line dielectric layer covering the channel of the channel layer; and performing a second thermal treatment to the channel layer and the word line dielectric layer. A top surface of the channel deviates less than three times its root mean square roughness.

Due to the design of the semiconductor device of the present disclosure, the surface roughness (or interface roughness) of the channel layer 150 may be improved and the stress of channel layer 150 may be reduced by employing the thermal treatment(s). As a result, the performance of the semiconductor device 1A may be improved. Additionally, the gate induced drain leakage may be reduced by employing the thicker word line dielectric layer consisting of the inner word line dielectric layer 171 and the outer word line dielectric layer 173. As a result, the performance (such as retention time) of the semiconductor device 1B may be improved. Furthermore, the outer word line dielectric layer 173 including the high-k dielectric material may improve drain current for the semiconductor device 1B.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for fabricating a semiconductor device, comprising:
providing a supporting substrate;
forming a channel layer parallel to a top surface of the supporting substrate, extending along a first direction, and comprising, in a sequence along the first direction, a drain, a channel, and a source;
conformally forming an interface insulating layer covering the channel layer;
performing a first thermal treatment to the channel layer and the interface insulating layer; and
forming a word line structure surrounding the channel, parallel to the top surface of the supporting substrate, and extending along a second direction perpendicular to the first direction;
wherein a top surface of the channel layer deviates less than three times its root mean square roughness.

2. The method for fabricating the semiconductor device of claim 1, wherein the first thermal treatment is performed at a temperature higher than 1000° C.

3. The method for fabricating the semiconductor device of claim 1, wherein the first thermal treatment is performed under a non-oxidizing atmosphere.

4. The method for fabricating the semiconductor device of claim 2, wherein the non-oxidizing atmosphere comprises argon, nitrogen, hydrogen, or a combination thereof.

5. The method for fabricating the semiconductor device of claim 1, wherein the first thermal treatment is a rapid thermal annealing process.

6. The method for fabricating the semiconductor device of claim 5, wherein the rapid thermal annealing process is performed between about 1 second and about 60 seconds.

7. The method for fabricating the semiconductor device of claim 1, further comprising forming a storage node structure contacting the drain.

8. The method for fabricating the semiconductor device of claim 7, further comprising forming a bit line contacting the source.

9. The method for fabricating the semiconductor device of claim 8, wherein the channel comprises doped polycrystalline silicon, doped polycrystalline germanium, or doped polycrystalline silicon germanium.

10. A method for fabricating a semiconductor device, comprising:
providing a supporting substrate;
forming a channel layer parallel to a top surface of the supporting substrate, extending along a first direction, and comprising, in a sequence along the first direction, a drain, a channel, and a source;
conformally forming a word line dielectric layer covering the channel of the channel layer; and
performing a second thermal treatment to the channel layer and the word line dielectric layer;
wherein a top surface of the channel deviates less than three times its root mean square roughness.

11. The method for fabricating the semiconductor device of claim 10, wherein the second thermal treatment is performed at a temperature higher than 1000° C.

12. The method for fabricating the semiconductor device of claim 10, wherein the second thermal treatment is performed under a non-oxidizing atmosphere.

13. The method for fabricating the semiconductor device of claim 12, wherein the non-oxidizing atmosphere comprises argon, nitrogen, hydrogen, or a combination thereof.

14. The method for fabricating the semiconductor device of claim 10, wherein the second thermal treatment is a rapid thermal annealing process.

15. The method for fabricating the semiconductor device of claim 14, wherein the rapid thermal annealing process is performed between about 1 second and about 60 seconds.

16. The method for fabricating the semiconductor device of claim 10, further comprising forming a word line conductive layer covering the word line dielectric layer, wherein the word line dielectric layer and the word line conductive layer together configure a word line structure.

17. The method for fabricating the semiconductor device of claim 16, further comprising forming a storage node structure contacting the drain.

18. The method for fabricating the semiconductor device of claim 17, further comprising forming a bit line contacting the source.

19. The method for fabricating the semiconductor device of claim 10, wherein the channel comprises doped polycrystalline silicon, doped polycrystalline germanium, or doped polycrystalline silicon germanium.
